(19) United States
(12) Patent Application Publication
(10) Pub. No.: US 2024/0047454 A1
(43) Pub. Date: Feb. 8, 2024

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Hidenori FUJII, Tokyo (JP); Sho TANAKA, Tokyo (JP); Shinya SONEDA, Tokyo (JP); Kazuya KONISHI, Tokyo (JP)

(73) Assignee: Mitsubishi Electric Corporation, Tokyo (JP)

(21) Appl. No.: 18/295,812

(22) Filed: Apr. 4, 2023

(30) Foreign Application Priority Data
Aug. 3, 2022 (JP) 2022-123676

(51) Int. Cl. H01L 27/06; H01L 29/32; H01L 29/861; H01L 29/739; H01L 21/268; H01L 29/66

(52) U.S. Cl. CPC H01L 27/0664; H01L 29/32; H01L 29/8613; H01L 29/7397; H01L 21/268; H01L 29/66348

(57) ABSTRACT

A semiconductor device includes a semiconductor region provided with a semiconductor layer on a main surface side, and a first defect provided in the semiconductor layer and extending from the main surface side in a direction including a component in a thickness direction. The semiconductor region includes at least one of a diode region in which a cathode layer is provided as the semiconductor layer or an IGBT region in which a collector layer is provided as the semiconductor layer.

### BACKGROUND OF THE INVENTION

### Field of the Invention

The present disclosure relates to a semiconductor device and a method for manufacturing the semiconductor device.

### Description of the Background Art

There has been proposed a semiconductor device in which an insulated gate bipolar transistor (IGBT) region and a diode region are provided on one semiconductor substrate. There has been proposed, in such a semiconductor device, a method for forming impurities by ion implantation and then activating the impurities as a method for forming a p-type collector layer in the IGBT region and forming an n⁺-type cathode layer in the diode region on a back surface side of the semiconductor substrate. In such a method, an amorphous layer formed by damage during ion implantation can be recrystallized at the same time as activation of impurities (for example, Japanese Patent No. 5194273).

The recrystallized amorphous layer functions as a low-resistance layer. However, when the resistance of the low-resistance layer is excessively low, there is a problem that a forward characteristic and a switching loss having a trade-off relationship cannot be adjusted unless a special step such as electron beam irradiation is added.

### SUMMARY

The present disclosure has been made in view of the above problem, and an object of the present disclosure is to provide a technique capable of adjusting a forward characteristic and a switching loss of at least one of a diode region or an IGBT region.

A semiconductor device according to the present disclosure includes a semiconductor region provided with a semiconductor layer on a main surface side of the semiconductor region, and a first defect provided in the semiconductor layer and extending from the main surface side in a direction including a component in a thickness direction, in which the semiconductor region includes at least one of a diode region provided with a cathode layer as the semiconductor layer or an IGBT region provided with a collector layer as the semiconductor layer.

The forward characteristic and the switching loss of at least one of the diode region or the IGBT region can be adjusted.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a plan view illustrating another configuration of the semiconductor device according to the first preferred embodiment;

FIG. 3 is a partially enlarged plan view illustrating a configuration of an IGBT region of the semiconductor device according to the first preferred embodiment;

FIGS. 4 and 5 are sectional views each illustrating the configuration of the IGBT region of the semiconductor device according to the first preferred embodiment;

FIG. 6 is a partially enlarged plan view illustrating a configuration of a diode region of the semiconductor device according to the first preferred embodiment;

FIGS. 7 and 8 are sectional views each illustrating the configuration of the diode region of the semiconductor device according to the first preferred embodiment;

FIG. 9 is a sectional view illustrating a configuration of a boundary region between the IGBT region and the diode region of the semiconductor device according to the first preferred embodiment;

FIG. 10 is an enlarged sectional view of the boundary region according to the first preferred embodiment;

FIG. 11 is a diagram illustrating a relationship between a depth from a back surface, an impurity concentration, and a carrier density in an on state in the diode region according to the first preferred embodiment;

FIG. 12 is a diagram illustrating a relationship between a depth from a back surface, an impurity concentration, and a carrier density in an on state in the IGBT region according to the first preferred embodiment;

FIGS. 13 and 14 are sectional views each illustrating a configuration of a terminal region of the semiconductor device according to the first preferred embodiment;

FIGS. 15A to 20B are sectional views each illustrating a method for manufacturing the semiconductor device according to the first preferred embodiment;

FIG. 21 is an enlarged sectional view of a boundary region according to a second preferred embodiment;

FIG. 22 is a diagram illustrating a relationship between a depth from a back surface, an impurity concentration, and a carrier density in an on state in a diode region according to the second preferred embodiment;

FIG. 23 is a diagram illustrating a relationship between a depth from a back surface, an impurity concentration, and a carrier density in an on state in an IGBT region according to the second preferred embodiment;

FIGS. 24 and 25 are enlarged sectional views of a boundary region according to a third preferred embodiment;

FIG. 26 is a sectional view illustrating a configuration of a terminal region of a semiconductor device according to a fourth preferred embodiment;

FIG. 27 is a sectional view illustrating a configuration of a terminal region of a semiconductor device according to a modification of the fourth preferred embodiment;

FIG. 28 is an enlarged sectional view of a boundary region according to a fifth preferred embodiment;

FIG. 29 is a diagram illustrating a relationship between a depth from a back surface, an impurity concentration, and a carrier density in an on state in a diode region according to the fifth preferred embodiment;

FIGS. 30 and 32 are diagrams each illustrating a relationship of the semiconductor device according to the first, second, and fifth preferred embodiments;

FIG. 31 is a diagram illustrating a relationship between the depth from the back surface, the impurity concentration, and the carrier density in the on state in the IGBT region according to the fifth preferred embodiment;

FIGS. 33 to 37 are sectional views each illustrating a method for manufacturing the semiconductor device according to the fifth preferred embodiment;

FIG. 38 is a sectional view illustrating a configuration of a terminal region of a semiconductor device according to a sixth preferred embodiment; and

FIG. 39 is a sectional view illustrating a configuration of a terminal region of a semiconductor device according to a modification of the sixth preferred embodiment.

### DESCRIPTION OF THE PREFERRED EMBODIMENTS

Hereinafter, preferred embodiments will be described with reference to the accompanying drawings. Characteristics described in the following preferred embodiments are merely examples, and all the characteristics are not necessarily essential. In the following description, similar components in a plurality of preferred embodiments are denoted by the same or similar reference numerals, and different components will be mainly described. Furthermore, in the following description, specific positions and directions such as “upper”, “lower”, “left”, “right”, “front”, or “back” do not necessarily coincide with actual positions and directions in practice. In addition, the fact that a certain portion has a higher concentration than other portions means that, for example, the average of the concentrations of the certain portion is higher than the average of the concentrations of the other portions. Conversely, the fact that a certain portion has a lower concentration than other portions means that, for example, the average of the concentrations of the certain portion is lower than the average of the concentrations of the other portions. In the following description, a first conductivity type is n-type and a second conductivity type is p-type, but the first conductivity type may be p-type and the second conductivity type may be n-type. In addition, n⁻ indicates that an impurity concentration is lower than n, and n⁺ indicates that the impurity concentration is higher than n. Similarly, p⁻ indicates that the impurity concentration is lower than p, and p⁺ indicates that the impurity concentration is higher than p.

### First Preferred Embodiment

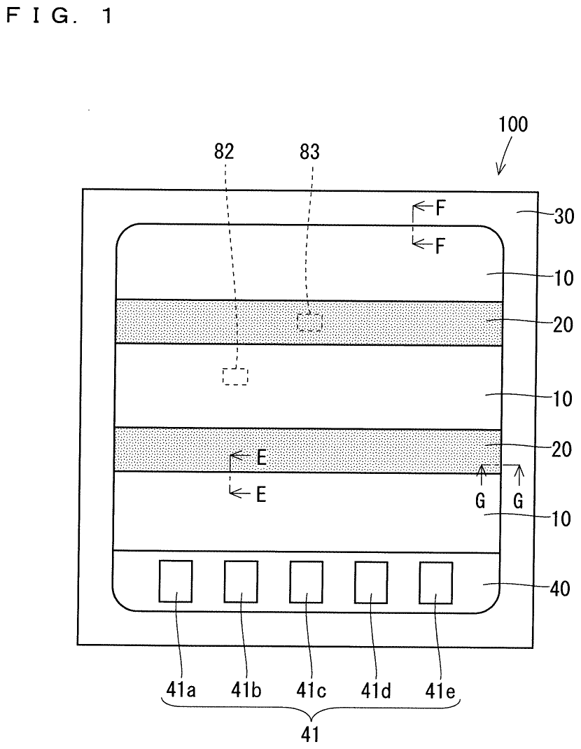

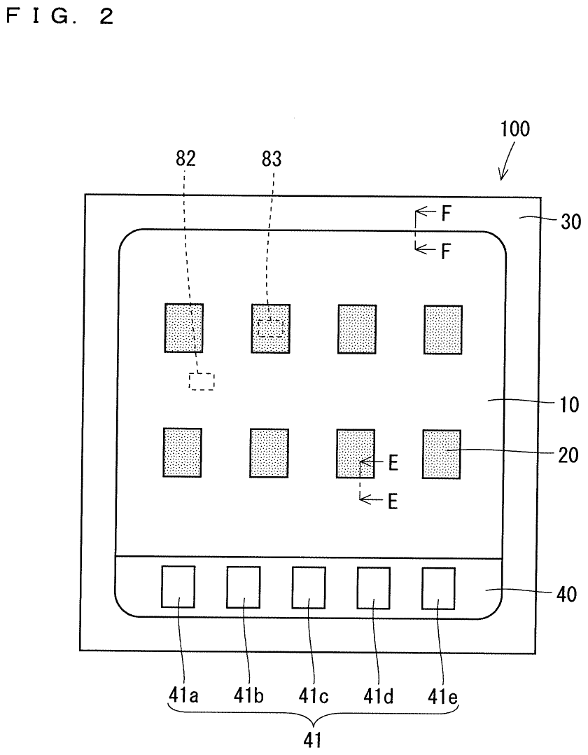

FIG. 1 is a plan view illustrating a semiconductor device that is a reverse conducting IGBT (RC-IGBT). FIG. 2 is a plan view illustrating another configuration of the semiconductor device which is the RC-IGBT according to the first preferred embodiment. In a semiconductor device 100 illustrated in FIG. 1, an IGBT region 10 and a diode region 20 are provided to be aligned in a stripe shape, and may be simply referred to as “stripe type” in the following description. In the semiconductor device 100 illustrated in FIG. 2, a plurality of diode regions 20 is provided in a longitudinal direction and a lateral direction, and the IGBT region 10 is provided around the diode regions 20 and may be simply referred to as an “island type” in the following description.

<Overall Planar Structure of Stripe Type>

In FIG. 1, the semiconductor device 100 includes the IGBT regions 10 and the diode regions 20 in one semiconductor device. Each of the IGBT regions 10 and the diode regions 20 extends from one end to the other end of the semiconductor device 100, and is alternately provided in a stripe shape in a direction orthogonal to an extending direction of the IGBT regions 10 and the diode regions 20. FIG. 1 illustrates three IGBT regions 10 and two diode regions 20, and illustrates a configuration in which all the diode regions 20 are sandwiched between the IGBT regions 10. However, the numbers of the IGBT regions 10 and the diode regions 20 are not limited thereto, and the number of the IGBT regions 10 may be three or more and three or less, and the number of the diode regions 20 may two or more and two or less. The IGBT regions 10 and the diode regions in FIG. 1 may be interchanged in location, or all the IGBT regions 10 may be sandwiched between the diode regions 20. The IGBT regions 10 and the diode regions 20 may be provided adjacent to each other one by one.

As illustrated in FIG. 1, a pad region 40 is provided adjacent to the IGBT region 10 on the lower side of the drawing. The pad region 40 is a region where a control pad 41 for controlling the semiconductor device 100 is provided. In the following description, the IGBT regions 10 and the diode regions 20 may be collectively referred to as a cell region. A terminal region 30 is provided around a combined region of the cell region and the pad region 40 in order to maintain a withstand voltage of the semiconductor device 100. A known withstand voltage holding structure may be appropriately provided in the terminal region 30. In the withstand voltage holding structure, for example, a field limiting ring (FLR) surrounding the cell region with a p-type terminal well layer of a p-type semiconductor or a variation of lateral doping (VLD) surrounding the cell region with a p-type well layer with a concentration gradient may be provided on the front surface side of the semiconductor device 100. Note that the number of ring-shaped p-type terminal well layers used for the FLR and a concentration distribution used for the VLD are only required to be appropriately selected in accordance with a withstand voltage design of the semiconductor device 100. In addition, a p-type terminal well layer may be provided over substantially the entire pad region 40, and an IGBT cell or a diode cell may be provided in the pad region 40.

The control pad 41 includes, for example, at least one of a current sense pad 41a, a Kelvin emitter pad 41b, a gate pad 41c, or a temperature sense diode pad 41d or 41e.

The current sense pad 41a is a control pad for detecting a current flowing through the cell region of the semiconductor device 100. When a current flows through the cell region of the semiconductor device 100, the current sense pad 41a is electrically connected to the cell region such that a current of a fraction to several tens of thousandth of the current flowing through the entire cell region flows through some of the IGBT cells or the diode cells of the cell region.

The Kelvin emitter pad 41b and the gate pad 41c are control pads to which a gate drive voltage for controlling on and off of the semiconductor device 100 is applied. The Kelvin emitter pad 41b is electrically connected to a p-type base layer of the IGBT cell. The gate pad 41c is electrically connected to a gate trench electrode of the IGBT cell. The Kelvin emitter pad 41b and the p-type base layer may be electrically connected via a p⁺-type contact layer. The temperature sense diode pads 41d and 41e are control pads electrically connected to an anode and a cathode of a temperature sense diode provided in the semiconductor device 100. A voltage between the anode and the cathode of the temperature sense diode (not shown) provided in the cell region is measured via the temperature sense diode pads 41d and 41e, and a temperature of the semiconductor device 100 is measured on the basis of the voltage.

<Overall Planar Structure of Island Type>

In FIG. 2, the semiconductor device 100 includes the IGBT region 10 and the diode regions 20 in one semiconductor device. A plurality of diode regions 20 is disposed to be aligned in each of the longitudinal direction and the lateral direction in the semiconductor device 100, and the periphery of the diode regions 20 is surrounded by the IGBT region 10. That is, the plurality of diode regions 20 is provided in an island shape in the IGBT region 10. FIG. 2 illustrates a configuration in which the diode regions 20 are provided in a matrix of four columns in the left-right direction of the drawing and two rows in the up-down direction on the drawing. However, the number and arrangement of the diode regions 20 are not limited thereto. One or a plurality of diode regions 20 is only required to be interspersed in the IGBT region 10, and the periphery of each diode region is only required to be surrounded by the IGBT region 10.

As illustrated in FIG. 2, the pad region 40 is provided adjacent to the lower side of the IGBT region 10 in the drawing. The pad region 40 is a region where a control pad 41 for controlling the semiconductor device 100 is provided. In this description, the IGBT region 10 and the diode regions 20 are also collectively referred to as a cell region. A terminal region 30 is provided around a combined region of the cell region and the pad region 40 in order to maintain a withstand voltage of the semiconductor device 100. A known withstand voltage holding structure may be appropriately provided in the terminal region 30. In the withstand voltage holding structure, for example, a FLR surrounding a combined region of the cell region and the pad region 40 with a p-type terminal well layer of a p-type semiconductor or a VLD surrounding the cell region with a p-type well layer with a concentration gradient may be provided on the front surface side of the semiconductor device 100. Note that the number of ring-shaped p-type terminal well layers used for the FLR and a concentration distribution used for the VLD are only required to be appropriately selected in accordance with a withstand voltage design of the semiconductor device 100. In addition, a p-type terminal well layer may be provided over substantially the entire pad region 40, and an IGBT cell or a diode cell may be provided in the pad region 40.

The control pad 41 includes, for example, at least one of a current sense pad 41a, a Kelvin emitter pad 41b, a gate pad 41c, or a temperature sense diode pad 41d or 41e.

The current sense pad 41a is a control pad for detecting a current flowing through the cell region of the semiconductor device 100. When a current flows through the cell region of the semiconductor device 100, the current sense pad 41a is electrically connected to the cell region such that a current of a fraction to several tens of thousandth of the current flowing through the entire cell region flows through some of the IGBT cells or the diode cells of the cell region.

The Kelvin emitter pad 41b and the gate pad 41c are control pads to which a gate drive voltage for controlling on and off of the semiconductor device 100 is applied. The Kelvin emitter pad 41b is electrically connected to a p-type base layer and an n⁺-type source layer of the IGBT cell. The gate pad 41c is electrically connected to a gate trench electrode of the IGBT cell. The Kelvin emitter pad 41b and the p-type base layer may be electrically connected via a p⁺-type contact layer. The temperature sense diode pads 41d and 41e are control pads electrically connected to an anode and a cathode of a temperature sense diode provided in the semiconductor device 100. A voltage between the anode and the cathode of the temperature sense diode (not shown) provided in the cell region is measured via the temperature sense diode pads 41d and 41e, and a temperature of the semiconductor device 100 is measured on the basis of the voltage.

<IGBT Region 10>

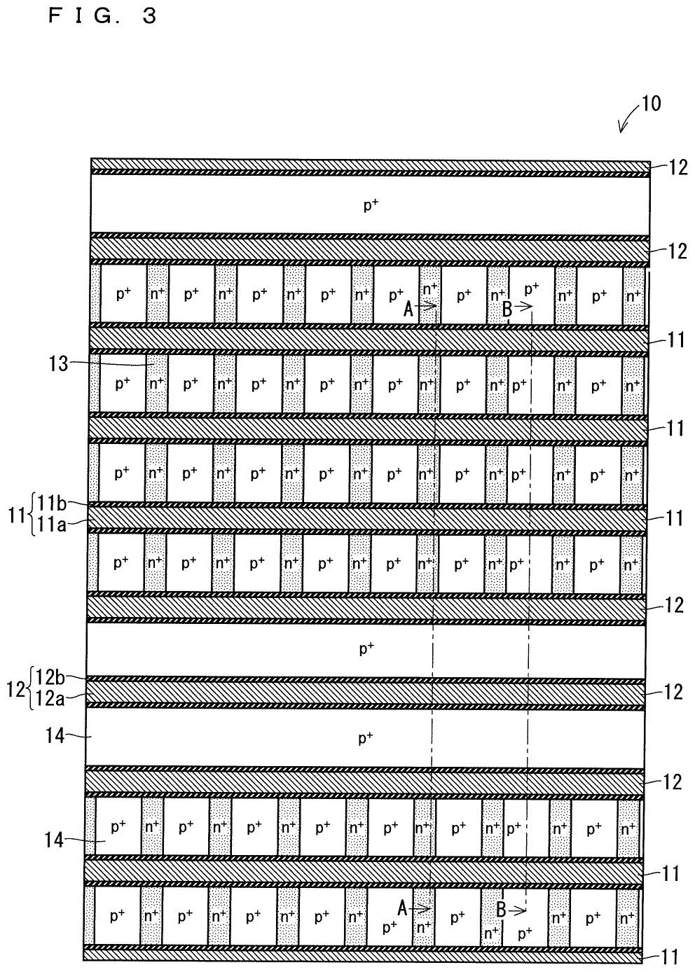

FIG. 3 is a partially enlarged plan view illustrating a configuration of the IGBT region 10 of the semiconductor device which is the RC-IGBT. Specifically, FIG. 3 is an enlarged view of a region surrounded by a broken line 82 in the semiconductor device 100 illustrated in FIGS. 1 and 2.

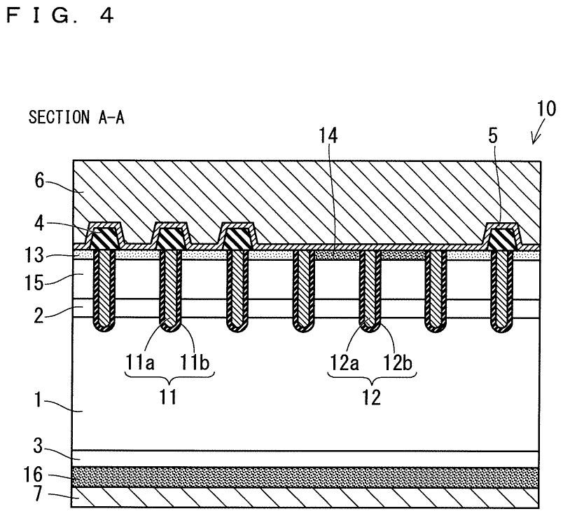

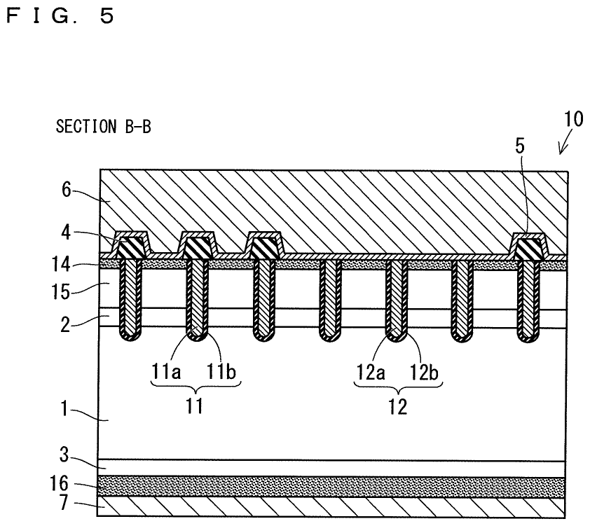

FIGS. 4 and 5 are sectional views illustrating the configuration of the IGBT region 10 of the semiconductor device which is the RC-IGBT. Specifically, FIG. 4 is a sectional view of the semiconductor device 100 illustrated in FIG. 3 along an alternate long and short dash line A-A, and FIG. 5 is a sectional view of the semiconductor device 100 illustrated in FIG. 3 along an alternate long and short dash line B-B.

As illustrated in FIG. 3, in the IGBT region 10, an active trench gate 11 and a dummy trench gate 12 are provided in a stripe shape. In the semiconductor device 100 of FIG. 1, the active trench gate 11 and the dummy trench gate 12 extend in a longitudinal direction of the IGBT region 10, and the longitudinal direction of the IGBT region 10 corresponds to a longitudinal direction of the active trench gate 11 and the dummy trench gate 12. On the other hand, in the semiconductor device 100 of FIG. 2, there is no particular distinction between the longitudinal direction and the lateral direction in the IGBT region 10, the left-right direction in the drawing may correspond to the longitudinal direction of the active trench gate 11 and the dummy trench gate 12, and the up-down direction in the drawing may correspond to the longitudinal direction of the active trench gate 11 and the dummy trench gate 12.

The active trench gate 11 is configured by providing a gate trench electrode 11a in a trench of a semiconductor substrate via a gate trench insulating film 11b. The dummy trench gate 12 is configured by providing a dummy trench electrode 12a in a trench of a semiconductor substrate via a dummy trench insulating film 12b. The gate trench electrode 11a of the active trench gate 11 is electrically connected to the gate pad 41c of FIGS. 1 and 2. The dummy trench electrode 12a of the dummy trench gate 12 is electrically connected to an emitter electrode provided on the front surface of the semiconductor device 100.

As illustrated in FIG. 3, an n⁺-type source layer 13 is provided on both sides in a width direction of the active trench gate 11 so as to be in contact with the gate trench insulating film 11b. The n⁺-type source layer 13 is a semiconductor layer containing, for example, arsenic or phosphorus as an n-type impurity, and the concentration of the n-type impurity is, for example, 1.0E+17/cm³ to 1.0E+20/cm³. The n⁺-type source layer 13 is provided alternately with the p⁺-type contact layer 14 along an extending direction of the active trench gate 11. The p⁺-type contact layer 14 is provided between two adjacent dummy trench gates 12 so as to be in contact with the dummy trench insulating film 12b. The p⁺-type contact layer 14 is a semiconductor layer containing, for example, boron or aluminum as a p-type impurity, and the concentration of the p-type impurity is, for example, 1.0E+15/cm³ to 1.0E+20/cm³.

As illustrated in FIG. 3, in the IGBT region 10 of the semiconductor device 100, three dummy trench gates 12 are aligned next to three active trench gates 11 arranged side by side. Then, three active trench gates 11 different from the three active trench gates 11 described above are aligned next to the aligned three dummy trench gates 12. The IGBT region 10 has a configuration in which a set of active trench gates 11 and a set of dummy trench gates 12 are alternately aligned as described above. In FIG. 3, the number of active trench gates 11 included in one set of active trench gates 11 is three, but is only required to be one or more. The number of dummy trench gates 12 included in a set of one dummy trench gate 12 may be one or more, and the number of dummy trench gates 12 may be zero. That is, all of the trench gates provided in the IGBT region 10 may be the active trench gates 11.

FIG. 4 is a sectional view of the semiconductor device 100 taken along the alternate long and short dash line A-A in FIG. 3, and is a sectional view of the IGBT region 10. The semiconductor device 100 includes an n⁻ type drift layer 1 including a semiconductor substrate. The n⁻-type drift layer 1 is a semiconductor layer containing, for example, arsenic or phosphorus as an n-type impurity, and the concentration of the n-type impurity is, for example, from 1.0E+12/cm³ to 1.0E+15/cm³. The concentration of the n-type impurity in the n⁺-type source layer 13 described above is higher than the concentration of the n-type impurity in the n⁻-type drift layer 1.

In FIG. 4, the range of the semiconductor substrate is a range from the n⁺-type source layer 13 and the p⁺-type contact layer 14 to a p-type collector layer 16. In FIG. 4, upper ends of the n⁺-type source layer 13 and the p⁺-type contact layer 14 in the drawing are referred to as a front surface of the semiconductor substrate, and a lower end of the p-type collector layer 16 in the drawing is referred to as a back surface which is a main surface of the semiconductor substrate. The semiconductor device 100 includes the n⁻-type drift layer 1 between a front surface and a back surface opposite to the front surface in the IGBT region 10 of the cell region. Note that the semiconductor substrate may include, for example, at least one of a wafer or an epitaxial growth layer. In addition, the semiconductor substrate may include a wide band gap semiconductor (silicon carbide (SiC), gallium nitride (GaN), or diamond) capable of stable operation at a high temperature.

As illustrated in FIG. 4, in the IGBT region 10, an n-type carrier accumulation layer 2 having a higher concentration of the n-type impurity than the n⁻-type drift layer 1 is provided on a front surface side of the n⁻-type drift layer 1. The n-type carrier accumulation layer 2 is a semiconductor layer containing, for example, arsenic or phosphorus as an n-type impurity, and the concentration of the n-type impurity is, for example, from 1.0E+13/cm³ to 1.0E+17/cm³. Note that the semiconductor device 100 may have a configuration in which the n⁻-type drift layer 1 is also provided in the region of the n-type carrier accumulation layer 2 illustrated in FIG. 4 without providing the n-type carrier accumulation layer 2. By providing the n-type carrier accumulation layer 2, energization loss when a current flows through the IGBT region 10 can be reduced. The n-type carrier accumulation layer 2 and the n⁻-type drift layer 1 may be collectively referred to as a drift layer.

The n-type carrier accumulation layer 2 is formed by ion-implanting n-type impurity into the semiconductor substrate constituting the n⁻-type drift layer 1 and then diffusing the n-type impurity implanted by annealing into the semiconductor substrate which is the n⁻-type drift layer 1.

A p-type base layer 15 is provided on a front surface side of the n-type carrier accumulation layer 2. The p-type base layer 15 is a semiconductor layer containing, for example, boron or aluminum as a p-type impurity, and the concentration of the p-type impurity is, for example, from 1.0E+12/cm³ to 1.0E+19/cm³. The p-type base layer 15 is in contact with the gate trench insulating film 11b of the active trench gate 11.

The n⁺-type source layer 13 in contact with the gate trench insulating film 11b of the active trench gate 11 is provided in a partial region on a front surface side of the p-type base layer 15, and the p⁺-type contact layer 14 is selectively provided in the remaining region on the front surface side of the p-type base layer 15. The n⁺-type source layer 13 and the p⁺-type contact layer 14 constitute the front surface of the semiconductor substrate. Note that the p⁺-type contact layer 14 is a region having a higher concentration of the p-type impurity than the p-type base layer 15. When required to be distinguished from each other, the p⁺-type contact layer 14 and the p-type base layer 15 may be referred to individually, and when not required to be distinguished from each other, the p⁺-type contact layer 14 and the p-type base layer 15 may be collectively referred to as a p-type base layer.

On a back surface side of the n⁻-type drift layer 1 of the semiconductor device 100, an n-type buffer layer 3 having a higher concentration of the n-type impurity than the n⁻-type drift layer 1 is provided. The n-type buffer layer 3 is provided to prevents a depletion layer extending from the p-type base layer 15 to the back surface side from punching through when the semiconductor device 100 is in an off state. The n-type buffer layer 3 may be formed by, for example, implanted phosphorus (P) or protons (H⁺), or may be formed by implanting both phosphorus (P) and protons (H⁺). The concentration of the n-type impurity in the n-type buffer layer 3 is, for example, from 1.0E+12/cm³ to 1.0E+18/cm³. Note that the semiconductor device 100 may have a configuration in which the n⁻-type drift layer 1 is provided in the region of the n-type buffer layer 3 illustrated in FIG. 4 without providing the n-type buffer layer 3. The n-type buffer layer 3 and the n⁻-type drift layer 1 may be collectively referred to as a drift layer.

The p-type collector layer 16 is provided on the back surface side of the n-type buffer layer 3 of the semiconductor device 100. That is, the p-type collector layer 16 is provided between the n⁻-type drift layer 1 and the back surface. The p-type collector layer 16 is a semiconductor layer containing, for example, boron or aluminum as a p-type impurity, and the concentration of the p-type impurity is, for example, from 1.0E+16/cm³ to 1.0E+20/cm³. The p-type collector layer 16 constitutes a back surface of the semiconductor substrate. The p-type collector layer 16 may be provided not only in the IGBT region 10 but also in the terminal region 30. The p-type collector layer 16 may be provided so as to partially protrude from the IGBT region 10 to the diode region 20.

As illustrated in FIG. 4, a trench that penetrates the p-type base layer 15 from the front surface of the semiconductor substrate and reaches the n⁻-type drift layer 1 is provided in the IGBT region 10 of the semiconductor device 100. The active trench gate 11 is configured by providing the gate trench electrode 11a in several trenches via the gate trench insulating film 11b. The gate trench electrode 11a faces the n⁻-type drift layer 1 via the gate trench insulating film 11b. The dummy trench gate 12 is configured by providing the dummy trench electrode 12a in several trenches via the dummy trench insulating film 12b. The dummy trench electrode 12a faces the n⁻-type drift layer 1 via the dummy trench insulating film 12b.

The gate trench insulating film 11b of the active trench gate 11 is in contact with the p-type base layer 15 and the n⁺-type source layer 13. When a gate drive voltage is applied to the gate trench electrode 11a, a channel is formed in the p-type base layer 15 in contact with the gate trench insulating film 11b of the active trench gate 11.

As illustrated in FIG. 4, an interlayer insulating film 4 is provided on the gate trench electrode 11a of the active trench gate 11. A barrier metal 5 is provided on a region of the front surface of the semiconductor substrate where the interlayer insulating film 4 is not provided, and on the interlayer insulating film 4. The barrier metal 5 may be, for example, a conductor containing titanium (Ti), and specifically, may be titanium nitride or TiSi obtained by alloying titanium and silicon (Si). As illustrated in FIG. 4, the barrier metal 5 is in ohmic contact with the n⁺-type source layer 13, the p⁺-type contact layer 14, and the dummy trench electrode 12a, and is electrically connected to the n⁺-type source layer 13, the p⁺-type contact layer 14, and the dummy trench electrode 12a. On the other hand, the barrier metal 5 is electrically insulated from the gate trench electrode 11a by the interlayer insulating film 4.

An emitter electrode 6 is provided on the barrier metal 5. The emitter electrode 6 may include, for example, an aluminum alloy such as an aluminum silicon alloy (Al—Si-based alloy), or may be an electrode including a plurality of layers of metal films in which a plating film is formed on an electrode including an aluminum alloy by electroless plating or electrolytic plating. The plating film formed by electroless plating or electrolytic plating may be, for example, a nickel (Ni) plating film. In a case where there is a fine region such as a region between adjacent interlayer insulating films 4 where favorable embedding cannot be obtained in the emitter electrode 6, a tungsten film having better embeddability than the emitter electrode 6 may be disposed in the fine region, and the emitter electrode 6 may be provided on the tungsten film. The emitter electrode 6 may be provided on the n⁺-type source layer 13, the p⁺-type contact layer 14, and the dummy trench electrode 12a without providing the barrier metal 5. In addition, the barrier metal 5 may be provided only on an n-type semiconductor layer such as the n⁻-type source layer 13. The barrier metal 5 and the emitter electrode 6 may be collectively referred to as an emitter electrode.

Although FIG. 4 illustrates the configuration in which the interlayer insulating film 4 is not provided on the dummy trench electrode 12a of the dummy trench gate 12, the interlayer insulating film 4 may be provided on the dummy trench electrode 12a of the dummy trench gate 12 in the sectional portion of FIG. 4. In a case where the interlayer insulating film 4 is provided on the dummy trench electrode 12a of the dummy trench gate 12 in the sectional portion of FIG. 4, the emitter electrode 6 and the dummy trench electrode 12a are only required to be electrically connected in another sectional portion.

A collector electrode 7 is provided on the back surface side of the p-type collector layer 16. Similarly to the emitter electrode 6, the collector electrode 7 may include an aluminum alloy or a plurality of layers of an aluminum alloy and a plating film. The collector electrode 7 may have a configuration different from the configuration of the emitter electrode 6. The collector electrode 7 is in ohmic contact with the p-type collector layer 16 and is electrically connected to the p-type collector layer 16.

FIG. 5 is a sectional view of the semiconductor device 100 taken along the alternate long and short dash line B-B in FIG. 3, and is a sectional view of the IGBT region 10. Unlike in the sectional portion taken along the alternate long and short dash line A-A illustrated in FIG. 4, in the sectional portion taken along the alternate long and short dash line B-B in FIG. 5, there is no n⁺-type source layer 13 being in contact with the active trench gate 11 and provided on the front surface side of the semiconductor substrate. That is, the n⁺-type source layer 13 illustrated in FIG. 3 is selectively provided on the front surface side of the p-type base layer. Note that the p-type base layer here includes the p-type base layer 15 and the p⁺-type contact layer 14.

<Diode Region 20>

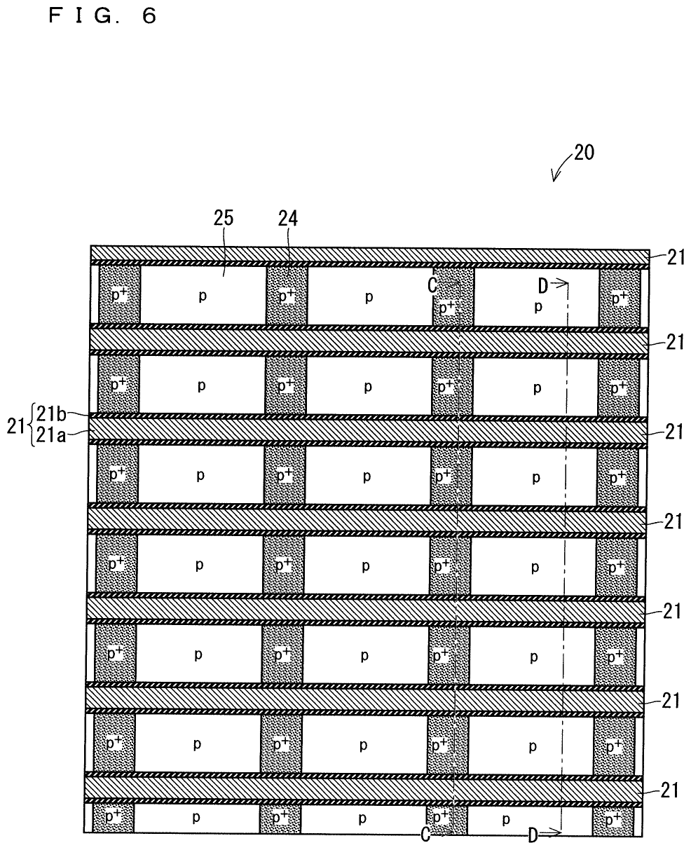

FIG. 6 is a partially enlarged plan view illustrating a configuration of the diode region 20 of the semiconductor device which is the RC-IGBT. Specifically, FIG. 6 is an enlarged view of a region surrounded by a broken line 83 in the semiconductor device 100 illustrated in FIGS. 1 and 2.

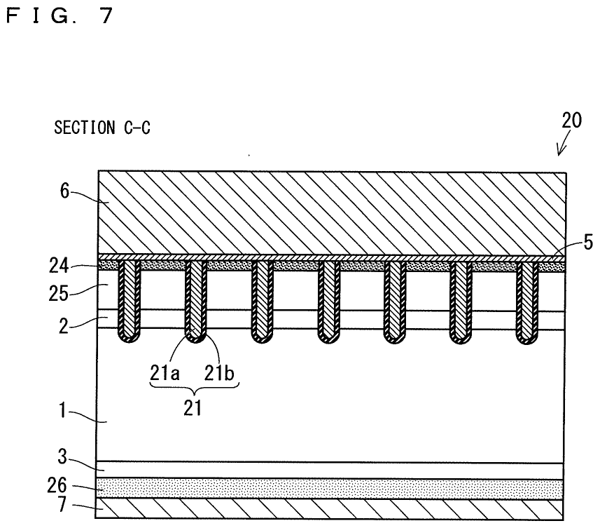

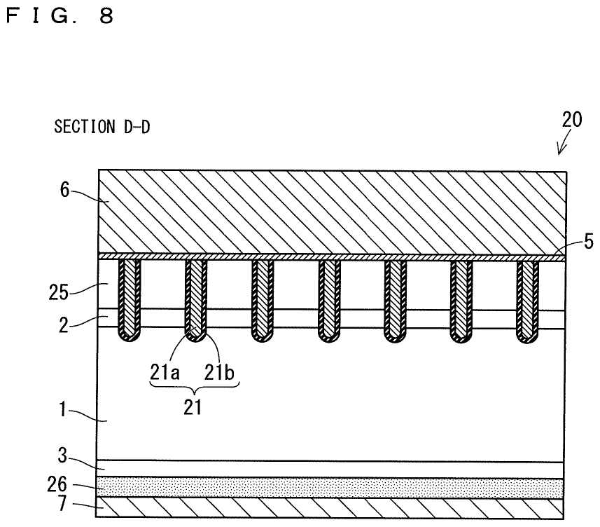

FIGS. 7 and 8 are sectional views illustrating the configuration of the diode region 20 of the semiconductor device which is the RC-IGBT. Specifically, FIG. 7 is a sectional view of the semiconductor device 100 illustrated in FIG. 6 along an alternate long and short dash line C-C, and FIG. 8 is a sectional view of the semiconductor device 100 illustrated in FIG. 6 along an alternate long and short dash line D-D.

A diode trench gate 21 is extended from one end toward the opposite end of the diode region 20 of the cell region along the front surface of the semiconductor device 100. The diode trench gate 21 is configured by providing a diode trench electrode 21a in a trench of the diode region 20 via a diode trench insulating film 21b. The diode trench electrode 21a faces the n⁻-type drift layer 1 via the diode trench insulating film 21b.

A p⁺-type contact layer 24 and a p-type anode layer 25 having a lower concentration of the p-type impurity than the p⁺-type contact layer 24 are provided between two adjacent diode trench gates 21. The p⁺-type contact layer 24 is a semiconductor layer containing, for example, boron or aluminum as a p-type impurity, and the concentration of the p-type impurity is, for example, 1.0E+15/cm³ to 1.0E+20/cm³. The p-type anode layer 25 is a semiconductor layer containing, for example, boron or aluminum as a p-type impurity, and the concentration of the p-type impurity is, for example, from 1.0E+12/cm³ to 1.0E+19/cm³. The p⁺-type contact layer 24 and the p-type anode layer 25 are alternately provided in the longitudinal direction of the diode trench gate 21.

FIG. 7 is a sectional view of the semiconductor device 100 taken along the alternate long and short dash line C-C in FIG. 6, and is a sectional view of the diode region 20. The semiconductor device 100 also includes an n⁻-type drift layer 1 including a semiconductor substrate in the diode region 20, similarly to the IGBT region 10. The n⁻-type drift layer 1 of the diode region 20 and the n⁻-type drift layer 1 of the IGBT region are continuously and integrally configured on the same semiconductor substrate.

In FIG. 7, the range of the semiconductor substrate is a range from the p⁺-type contact layer 24 to the n⁺-type cathode layer 26. In FIG. 7, an upper end of the p⁺-type contact layer 24 in the drawing are referred to as a front surface of the semiconductor substrate, and a lower end of the n⁺-type cathode layer 26 in the drawing is referred to as a back surface of the semiconductor substrate. A front surface of the diode region 20 and a front surface of the IGBT region 10 are included in the same plane, and a back surface of the diode region 20 and a back surface of the IGBT region 10 are included in the same plane.

As illustrated in FIG. 7, in the diode region 20, similarly to the IGBT region 10, the n-type carrier accumulation layer 2 is provided on the front surface side of the n⁻-type drift layer 1, and the n-type buffer layer 3 is provided on the back surface side of the n⁻-type drift layer 1. The n-type carrier accumulation layer 2 and the n-type buffer layer 3 provided in the diode region 20 may have the same configuration as the n-type carrier accumulation layer 2 and the n-type buffer layer 3 provided in the IGBT region 10. The n-type carrier accumulation layer 2 is not necessarily provided in the IGBT region 10 and the diode region 20. For example, the n-type carrier accumulation layer 2 may be provided in the IGBT region 10 but not in the diode region 20. Similarly to the IGBT region 10, the n⁻-type drift layer 1, the n-type carrier accumulation layer 2, and the n-type buffer layer 3 may be collectively referred to as a drift layer.

The p-type anode layer 25 is provided on the front surface side of the n-type carrier accumulation layer 2. The p-type anode layer 25 is provided between the n⁻-type drift layer 1 and the front surface. The p-type anode layer 25 and the p-type base layer 15 may be simultaneously formed by making the concentration of the p-type impurity of the p-type anode layer 25 the same as the concentration of the p-type impurity of the p-type base layer 15 of the IGBT region 10. The concentration of the p-type impurity of the p-type anode layer 25 may be lower than the concentration of the p-type impurity of the p-type base layer 15 of the IGBT region 10 to reduce an amount of holes implanted into the diode region 20 during diode operation. By reducing the amount of holes implanted during diode operation, recovery loss during diode operation can be reduced.

The p⁺-type contact layer 24 is provided on the front surface side of the p-type anode layer 25. The concentration of the p-type impurity of the p⁺-type contact layer 24 may be the same as or different from the concentration of the p-type impurity of the p⁺-type contact layer 14 of the IGBT region 10. The p⁺-type contact layer 24 constitutes the front surface of the semiconductor substrate. Note that the p⁺-type contact layer 24 is a region having a higher concentration of the p-type impurity than the p-type anode layer 25. The p⁺-type contact layer 24 and the p-type anode layer 25 may be referred to individually when required to be distinguished from each other, and the p⁺-type contact layer 24 and the p-type anode layer 25 may be collectively referred to as a p-type anode layer when not required to be distinguished from each other.

The n⁺-type cathode layer 26 is provided on the back surface side of the n-type buffer layer 3 of the semiconductor device 100. That is, the n⁺-type cathode layer 26 is provided between the n⁻-type drift layer 1 and the back surface. The n⁺-type cathode layer 26 is a semiconductor layer containing, for example, arsenic or phosphorus as an n-type impurity, and the concentration of the n-type impurity is, for example, 1.0E+16/cm³ to 1.0E+21/cm³. The n⁺-type cathode layer 26 is provided in a part or all of the diode region 20. The n⁺-type cathode layer 26 constitutes the back surface of the semiconductor substrate. Although not shown, a p-type cathode layer which is a p-type semiconductor may be provided by further selectively implanting p-type impurity into a part of the region where the n⁺-type cathode layer 26 is formed.

As illustrated in FIG. 7, a trench that penetrates the p-type anode layer 25 from the front surface of the semiconductor substrate and reaches the n⁻-type drift layer 1 is provided in the diode region 20 of the semiconductor device 100. The diode trench gate 21 is configured by providing the diode trench electrode 21a in the trench of the diode region 20 via the diode trench insulating film 21b. The diode trench electrode 21a faces the n⁻-type drift layer 1 via the diode trench insulating film 21b.

As illustrated in FIG. 7, a barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode 21a and the p⁺-type contact layer 24. The barrier metal 5 may have the same configuration as the barrier metal 5 in the IGBT region 10.

An emitter electrode 6 is provided on the barrier metal 5. The emitter electrode 6 provided in the diode region 20 is configured to be continuous with the emitter electrode 6 provided in the IGBT region 10. As in the case of the IGBT region 10, the diode trench electrode 21a and the p⁺-type contact layer 24 may be in ohmic contact with the emitter electrode 6 without providing the barrier metal 5.

Although FIG. 7 illustrates the configuration in which the interlayer insulating film 4 as in FIG. 4 is not provided on the diode trench electrode 21a of the diode trench gate 21, the interlayer insulating film 4 may be provided on the diode trench electrode 21a in the sectional portion of FIG. 7. In a case where the interlayer insulating film 4 is provided on the diode trench electrode 21a of the diode trench gate 21 in the sectional portion of FIG. 7, the emitter electrode 6 and the diode trench electrode 21a are only required to be electrically connected in another sectional portion.

A collector electrode 7 is provided on the back surface of side the n⁺-type cathode layer 26. Similarly to the emitter electrode 6, the collector electrode 7 of the diode region 20 is configured to be continuous with the collector electrode 7 provided in the IGBT region 10. The collector electrode 7 is in ohmic contact with the n⁺-type cathode layer 26 and is electrically connected to the n⁺-type cathode layer 26.

FIG. 8 is a sectional view of the semiconductor device 100 taken along the alternate long and short dash line D-D in FIG. 6, and is a sectional view of the diode region 20. Unlike in the sectional portion taken along the alternate long and short dash line C-C illustrated in FIG. 7, in the sectional portion taken along the alternate long and short dash line D-D in FIG. 8, the p⁺-type contact layer 24 is not provided between the p-type anode layer 25 and the barrier metal 5, and the p-type anode layer 25 is the front surface of the semiconductor substrate. That is, the p⁺-type contact layer 24 illustrated in FIG. 7 is selectively provided on the front surface side of the p-type anode layer 25.

<Configuration of Boundary Region Between IGBT Region 10 and Diode Region 20>

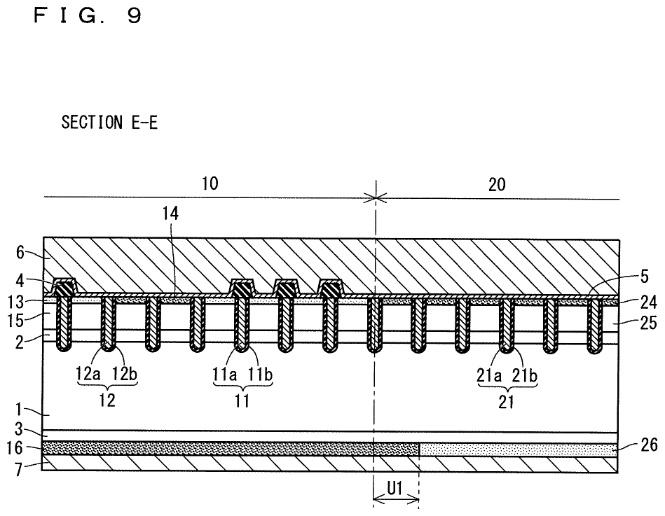

FIG. 9 is a sectional view illustrating a configuration of a boundary region between the IGBT region 10 and the diode region 20 of the semiconductor device which is the RC-IGBT. Specifically, FIG. 9 is a sectional view along an alternate long and short dash line E-E in the semiconductor device 100 illustrated in FIGS. 1 and 2.

As illustrated in FIG. 9, the p-type collector layer 16 provided on the back surface side of the IGBT region 10 and the n⁺-type cathode layer 26 provided on the back surface side of the diode region 20 are adjacent to each other in the in-plane direction of the semiconductor substrate. Then, the p-type collector layer 16 is provided so as to protrude toward the diode region 20 by a distance U1 from a boundary between the IGBT region 10 and the diode region 20.

As described above, by providing the p-type collector layer 16 so as to protrude toward the diode region 20, a distance between the n⁺-type cathode layer 26 of the diode region 20 and the active trench gate 11 can be increased. Therefore, even when a gate drive voltage is applied to the gate trench electrode 11a during freewheeling diode operation, a current can be suppressed from flowing from the channel formed adjacent to the active trench gate 11 of the IGBT region 10 to the n⁺-type cathode layer 26. The distance U1 may be, for example, 100 μm. Note that the distance U1 may be 0 or a distance smaller than 100 μm depending on the application of the semiconductor device 100 which is the RC-IGBT.

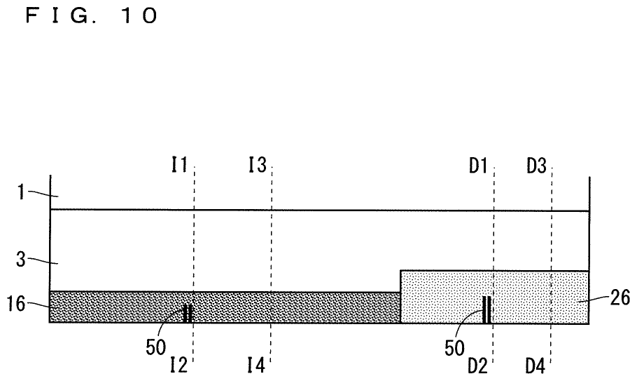

FIG. 10 is an enlarged sectional view of a boundary region according to the first preferred embodiment. FIG. 10 illustrates the n-type buffer layer 3, the p-type collector layer 16, and the n⁺-type cathode layer 26 on the back surface side of the semiconductor substrate.

In the first preferred embodiment, the n⁺-type cathode layer 26 is provided as the semiconductor layer on the back surface side of the diode region 20 included in a semiconductor region, and a first defect 50 extending from the back surface side in a direction including a component in a thickness direction is provided in the n⁺-type cathode layer 26. The p-type collector layer 16 is provided as the semiconductor layer on the back surface side of the IGBT region 10 included in a semiconductor region, and a first defect 50 extending from the back surface side in the direction including a component in the thickness direction is provided in the p-type collector layer 16. As for the direction in which the first defect 50 extends, the component in the thickness direction (a component in the up-down direction in FIG. 10) is larger than a component in the in-plane direction (a component in the left-right direction in FIG. 10), and the first defect 50 extends in substantially the same direction as the thickness direction. Note that the first defect 50 is locally provided in the n⁺-type cathode layer 26 and the p-type collector layer 16.

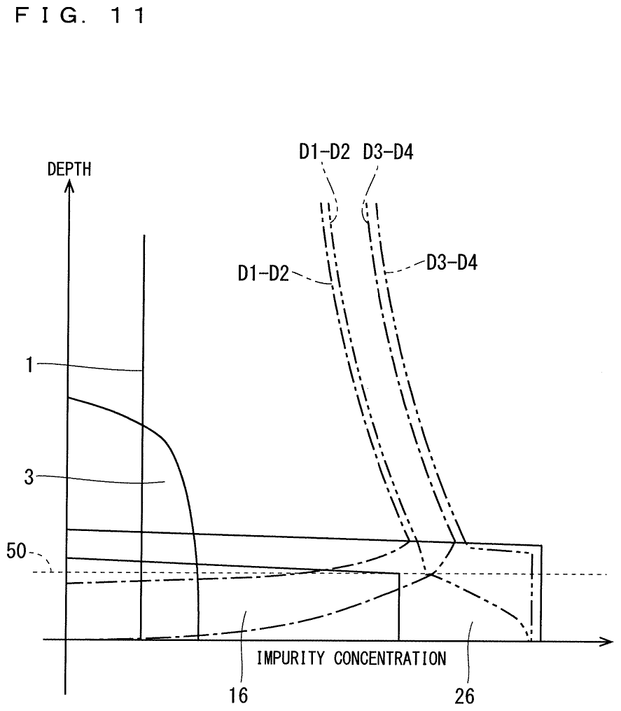

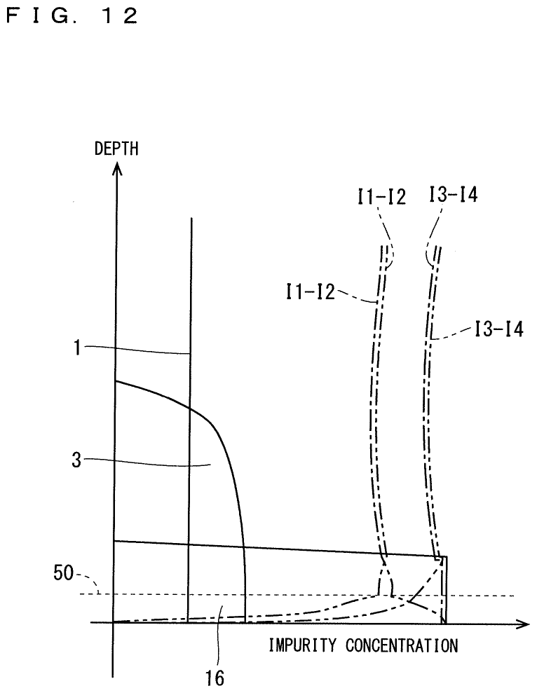

FIG. 11 is a diagram illustrating a relationship between a depth from the back surface, an impurity concentration, and a carrier density in an on state in the diode region according to the first preferred embodiment. FIG. 11 illustrates, as the carrier density of the n⁺-type cathode layer 26, the density of holes and electrons in a portion along a line D1-D2 where the first defect 50 of FIG. 10 is provided, and the density of holes and electrons in a portion along a line D3-D4 where the first defect 50 of FIG. 10 is not provided. The density of holes is indicated by an alternate long and short dash line, the density of electrons is indicated by an alternate long and two short dashes line, and the position of the portion farthest from the back surface of the first defect 50 is indicated by a dotted line. The same applies to FIG. 12 and the like which are similar to FIG. 11.

The carrier density of the portion along the line D1-D2 where the first defect 50 is provided is lower than the carrier density of the portion along the line D3-D4 where the first defect 50 is not provided. As the component in the thickness direction in the direction in which the first defect 50 extends increases, and as the density of the first defect 50 in the n⁺-type cathode layer 26 increases, the carrier density of the portion along the line D1-D2 where the first defect 50 is provided decreases. As a result, a forward characteristic is deteriorated but a switching loss is improved in the portion where the first defect 50 is provided as compared with the portion where the first defect 50 is not provided.

Therefore, by controlling the component and density in the thickness direction of the first defect 50 provided in the n⁺-type cathode layer 26, the forward characteristic and the switching loss having a trade-off relationship can be adjusted. The component and density in the thickness direction of the first defect 50 can be controlled by adjusting power of laser annealing capable of recrystallizing an amorphous layer to be described later and by time for laser irradiation.

FIG. 12 is a diagram illustrating a relationship between a depth from the back surface, an impurity concentration, and a carrier density in the on state in the IGBT region according to the first preferred embodiment. FIG. 12 illustrates, as the carrier density of the p-type collector layer 16, the density of holes and electrons in a portion along a line 11-12 where the first defect 50 of FIG. 10 is provided, and the density of holes and electrons in a portion along a line 13-14 where the first defect 50 of FIG. 10 is not provided.

The carrier density of the portion along the line 11-12 where the first defect 50 is provided is lower than the carrier density of the portion along the line 13-14 where the first defect 50 is not provided. That is, a tendency in a case where the first defect 50 is provided in the p-type collector layer 16 of the IGBT region 10 is substantially the same as a tendency in a case where the first defect 50 is provided in the n⁺-type cathode layer 26 of the diode region 20 described above. Therefore, by controlling the component and density in the thickness direction of the first defect 50 provided in the p-type collector layer 16, the forward characteristic and the switching loss having a trade-off relationship can be adjusted. The component and density in the thickness direction of the first defect 50 can be controlled by adjusting power of laser annealing capable of recrystallizing an amorphous layer to be described later and by time for laser irradiation.

<Terminal Region 30>

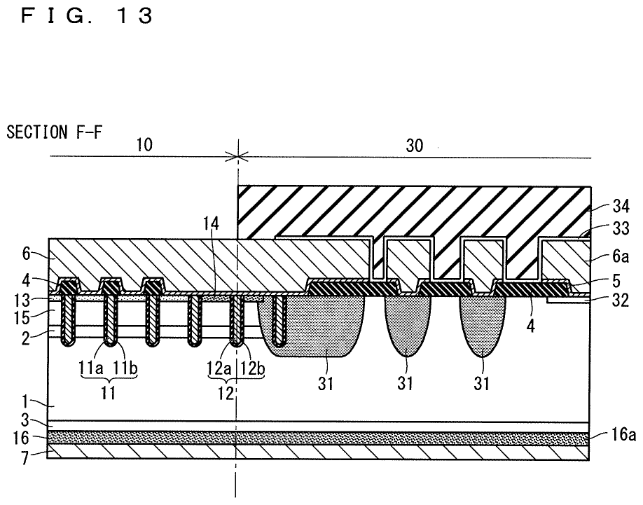

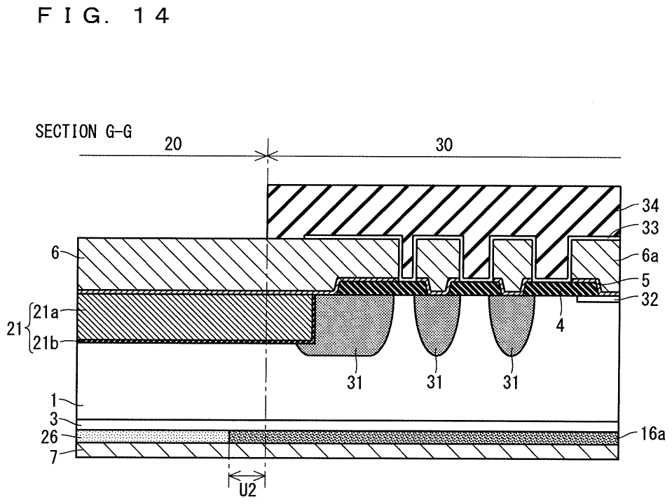

FIGS. 13 and 14 are sectional views illustrating a configuration of the terminal region of the semiconductor device 100 which is the RC-IGBT. Specifically, FIG. 13 is a sectional view taken along an alternate long and short dash line F-F illustrated in FIGS. 1 and 2, and is a sectional view from the IGBT region 10 to the terminal region 30. FIG. 14 is a sectional view taken along an alternate long and short dash line G-G illustrated in FIG. 1, and is a sectional view from the diode region 20 to the terminal region 30.

As shown in FIGS. 13 and 14, the terminal region 30 of the semiconductor device 100 has n⁻-type drift layer 1 between the front surface and the back surface of the semiconductor substrate. The front surface and the back surface of the terminal region 30 are included in the same plane as the front surface and the back surface of the IGBT region 10 and the diode region 20, respectively. In addition, the n⁻-type drift layer 1 of the terminal region 30 has the same configuration as the n⁻-type drift layer 1 in each of the IGBT region 10 and the diode region 20, and is continuously and integrally configured.

A p-type terminal well layer 31 is selectively provided on the front surface side of the n⁻-type drift layer 1, that is, between the front surface of the semiconductor substrate and the n⁻-type drift layer 1. The p-type terminal well layer 31 is a semiconductor layer containing, for example, boron or aluminum as a p-type impurity, and the concentration of the p-type impurity is, for example, from 1.0E+14/cm³ to 1.0E+19/cm³. The p-type terminal well layer 31 is provided to surround the cell region including the IGBT region 10 and the diode region 20. The p-type terminal well layers 31 are provided in a plurality of ring shapes, and the number of the p-type terminal well layers 31 to be provided is appropriately selected in accordance with the withstand voltage design of the semiconductor device 100. Furthermore, an n⁺-type channel stopper layer 32 is provided on a further outer edge of the p type terminal well layer 31, and the n⁺-type channel stopper layer 32 surrounds the p-type terminal well layer 31 in plan view.

A p-type terminal collector layer 16a is provided between the n⁻-type drift layer 1 of the terminal region 30 and the back surface of the semiconductor substrate. The p-type terminal collector layer 16a is continuously and integrally configured with the p-type collector layer 16 provided in the IGBT region 10 of the cell region. Therefore, the p-type terminal collector layer 16a may be referred to as a p-type collector layer.

In the configuration in which the diode region 20 is provided adjacent to the terminal region 30 as in the semiconductor device 100 illustrated in FIG. 1, as illustrated in FIG. 14, an end of the p-type terminal collector layer 16a close to the diode region 20 protrudes toward the diode region 20 by a distance U2. Such a configuration can increase a distance between the n⁺-type cathode layer 26 and the p-type terminal well layer 31 of the diode region 20, and therefore can prevent the p-type terminal well layer 31 from operating as an anode of a diode. The distance U2 may be, for example, 100 μm. The collector electrode 7 is provided on the back surface of the semiconductor substrate. The collector electrode 7 is continuously and integrally configured from the cell region including the IGBT region 10 and the diode region 20 to the terminal region 30.

On the other hand, the emitter electrode 6 continuous from the cell region and a terminal electrode 6a structurally separated from the emitter electrode 6 are provided on the front surface of the semiconductor substrate of the terminal region 30. The emitter electrode 6 and the terminal electrode 6a are electrically connected via a semi-insulating film 33. The semi-insulating film 33 may be, for example, semi-insulating silicon nitride (sinSiN). The terminal electrode 6a is electrically connected to each of the p-type terminal well layer 31 and the n⁺-type channel stopper layer 32 via a contact hole of the interlayer insulating film 4 provided on the front surface of the terminal region 30. The terminal region 30 is provided with a terminal protection film 34 that covers the emitter electrode 6, the terminal electrode 6a, and the semi-insulating film 33. The terminal protection film 34 is, for example, polyimide.

<Method for Manufacturing RC-IGBT>

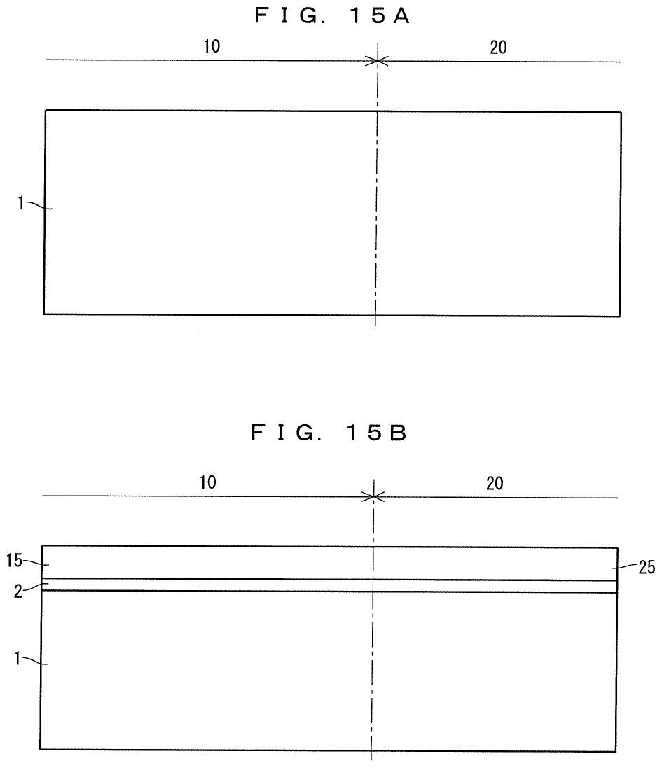

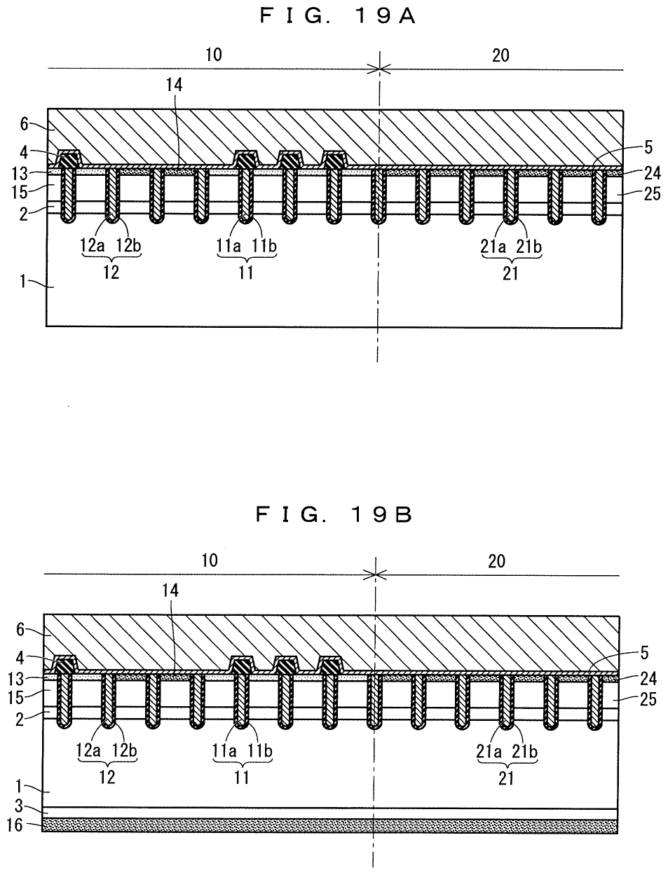

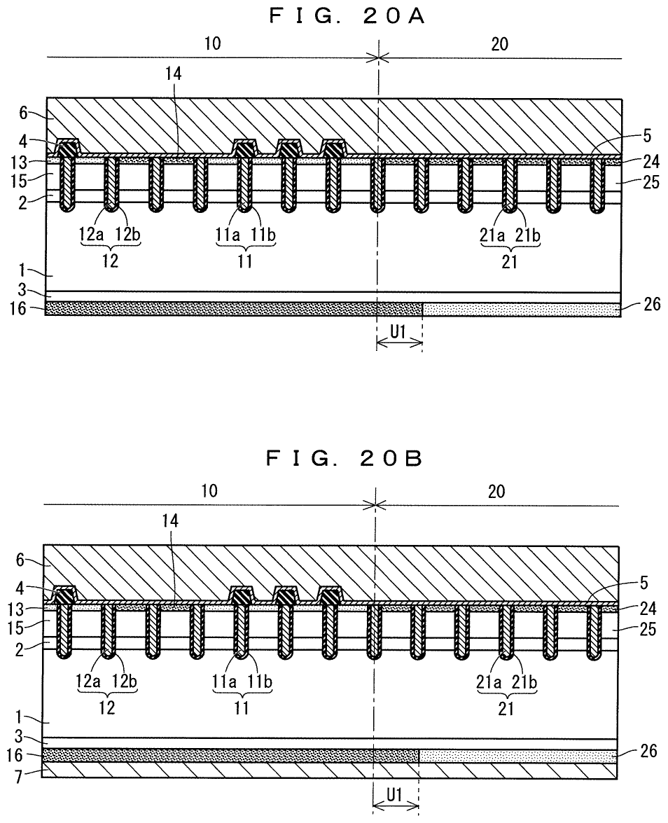

FIGS. 15A to 20B are sectional views illustrating a method for manufacturing the semiconductor device which is the RC-IGBT. FIGS. 15A to 18B are views illustrating a step of mainly forming a front surface side of the boundary region of FIG. 9 of the semiconductor device 100, and FIGS. 19A to 20B are views illustrating a step of mainly forming a back surface side of the boundary region of FIG. 9 of the semiconductor device 100.

First, as illustrated in FIG. 15A, a semiconductor substrate constituting the n⁻-type drift layer 1 is prepared. The semiconductor substrate may be, for example, an FZ wafer manufactured by a floating zone (FZ) method, an MCZ wafer manufactured by a magnetic field applied CZochralki (MCZ) method, or an n-type wafer containing the n-type impurity. The concentration of the n-type impurity contained in the semiconductor substrate is appropriately selected in accordance with the withstand voltage of the semiconductor device to be manufactured. For example, in a semiconductor device having a withstand voltage of 1200 V, the concentration of the n-type impurity is adjusted such that a specific resistance of the n⁻-type drift layer 1 constituting the semiconductor substrate is about 40 to 120 S2 cm. As illustrated in FIG. 15A, in the step of preparing the semiconductor substrate, the entire semiconductor substrate is the n⁻-type drift layer 1. By implanting p-type or n-type impurity ions from the front surface side or the back surface side of such a semiconductor substrate and then diffusing the impurity ions into the semiconductor substrate by heat treatment or the like, a p-type or n-type semiconductor layer is appropriately formed, and the semiconductor device 100 is manufactured.

As illustrated in FIG. 15A, the semiconductor substrate constituting the n⁻-type drift layer 1 has a region to be the IGBT region 10 and the diode region 20. Although not shown, a region to be the terminal region 30 and the like is provided around the region to be the IGBT region 10 and the diode region 20. Hereinafter, a method for manufacturing the configurations of the IGBT region 10 and the diode region 20 of the semiconductor device 100 will be mainly described, but the terminal region 30 and the like of the semiconductor device 100 may be manufactured by a known manufacturing method. For example, when the FLR having the p-type terminal well layer 31 as the withstand voltage holding structure is formed in the terminal region 30, the FLR may be formed by implanting p-type impurity ions before processing the IGBT region 10 and the diode region 20 of the semiconductor device 100. Alternatively, when a p-type impurity is ion-implanted into the IGBT region 10 or the diode region 20 of the semiconductor device 100, p-type impurity ions may be implanted simultaneously to form FLRs.

Next, as illustrated in FIG. 15B, an n-type impurity such as phosphorus (P) is implanted from the front surface side of the semiconductor substrate to form the n-type carrier accumulation layer 2. In addition, a p-type impurity such as boron (B) is implanted from the front surface side of the semiconductor substrate to form the p-type base layer 15 and the p-type anode layer 25. The n-type carrier accumulation layer 2, the p-type base layer 15, and the p-type anode layer 25 are formed by implanting impurity ions into the semiconductor substrate and then diffusing the impurity ions by heat treatment. Since the ion implantation of the n-type impurity and the p-type impurity is performed after mask processing is performed on the front surface of the semiconductor substrate, various layers are selectively formed on the front surface side of the semiconductor substrate. The n-type carrier accumulation layer 2, the p-type base layer and the p-type anode layer 25 are formed in the IGBT region 10 and the diode region and are connected to the p-type terminal well layer 31 in the terminal region 30. The mask processing is processing of applying a resist on a semiconductor substrate, forming openings in a predetermined region of the resist by a photolithography technique, and forming a mask on the semiconductor substrate in order to perform ion implantation and etching on the predetermined region of the semiconductor substrate through the openings. By the mask processing and the ion implantation described above, the n-type carrier accumulation layer 2, the p-type base layer 15, and the p-type anode layer 25 are selectively formed on the front surface side of the IGBT region 10 and the diode region 20. Similarly, the p-type terminal well layer 31 is selectively formed in the terminal region 30.

The p-type impurity of the p-type base layer 15 and the p-type anode layer 25 may be ion-implanted simultaneously. In this case, the p-type base layer 15 and the p-type anode layer 25 have the same depth and p-type impurity concentration. Alternatively, the p-type impurity of the p-type base layer 15 and the p-type anode layer 25 may be separately ion-implanted by the mask processing to make the depth and the p-type impurity concentration of the p-type base layer 15 and the p-type anode layer 25 different from each other.

The p-type impurity of the p-type terminal well layer 31 not illustrated in FIG. 15B and the p-type anode layer 25 may be ion-implanted simultaneously. In this case, the p-type terminal well layer 31 and the p-type anode layer 25 have the same depth and p-type impurity concentration. Alternatively, the p-type impurity of the p-type terminal well layer 31 and the p-type anode layer 25 may be separately ion-implanted by the mask processing to make the depth and the p-type impurity concentration of the p-type terminal well layer 31 and the p-type anode layer 25 different from each other. Alternatively, the p-type impurity of the p-type terminal well layer 31 and the p-type anode layer 25 can be simultaneously ion-implanted by using masks having different aperture ratios to make the p-type impurity concentration of the p-type terminal well layer 31 and the p-type anode layer 25 different from each other. In this case, any one or both of the masks is only required to be a mesh-like mask to make the aperture ratio of the masks different. Similarly, the p-type impurity of the p-type terminal well layer 31, the p-type base layer 15, and the p-type anode layer 25 may be simultaneously ion-implanted by using masks having different aperture ratios.

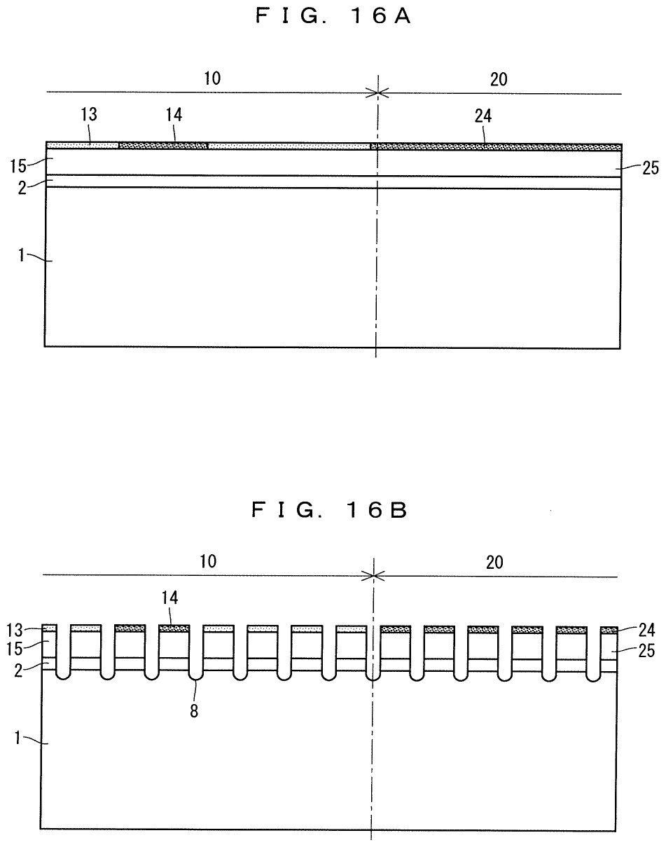

Next, as illustrated in FIG. 16A, an n-type impurity is selectively implanted into the front surface side of the p-type base layer 15 of the IGBT region 10 by the mask processing to form the n⁺-type source layer 13. The n-type impurity to be implanted may be, for example, arsenic (As) or phosphorus (P). In addition, by the mask processing, a p-type impurity is implanted into the front surface side of the p-type base layer 15 of the IGBT region 10 to form the p⁺-type contact layer 14, and a p-type impurity is implanted into the front surface side of the p-type anode layer 25 of the diode region 20 to form the p⁺-type contact layer 24. The p-type impurity to be implanted may be, for example, boron, aluminum, or the like.

Next, as illustrated in FIG. 16B, a trench 8 that penetrates the p-type base layer and the p-type anode layer 25 from the front surface side of the semiconductor substrate and reaches the n⁻-type drift layer 1 is formed. In the IGBT region 10, a sidewall of the trench 8 penetrating the n⁺-type source layer 13 includes a part of the n⁺-type source layer 13. In the IGBT region 10, the sidewall of the trench 8 penetrating the p⁺-type contact layer 14 includes a part of the p⁺-type contact layer 14. In the diode region 20, the sidewall of the trench 8 penetrating the p⁺-type contact layer 24 includes a part of the p⁺-type contact layer 24.

For example, the trench 8 is formed by depositing an oxide film such as SiO 2 on a semiconductor substrate, forming openings in the oxide film at a portion where the trench 8 is to be formed by mask processing, and etching the semiconductor substrate by using the oxide film having the openings as a mask. In FIG. 16B, the IGBT region 10 and the diode region 20 are formed with the same pitch of the trenches 8, but the IGBT region and the diode region 20 may have a different pitch of the trench 8. The pitch of the trenches 8 and a pattern in plan view can be appropriately changed in accordance with a mask pattern of the mask processing.

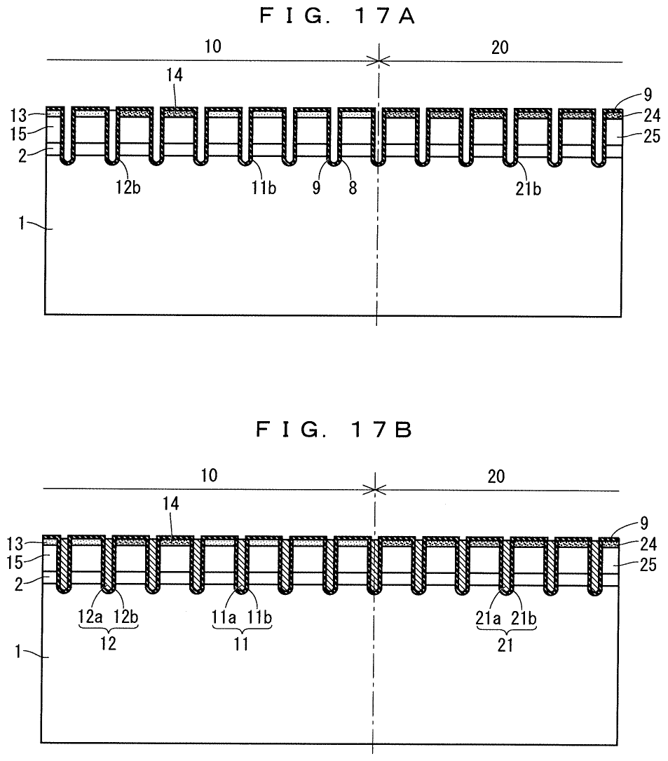

Next, as illustrated in FIG. 17A, the semiconductor substrate is heated in an atmosphere containing oxygen to form an oxide film 9 on the inner walls of the trenches 8 and the front surface of the semiconductor substrate. The oxide film 9 formed in the trench 8 of the IGBT region 10 becomes the gate trench insulating film 11b of the active trench gate 11 and the dummy trench insulating film 12b of the dummy trench gate 12. The oxide film 9 formed in the trench 8 of the diode region 20 becomes the diode trench insulating film 21b. The oxide film 9 formed on the front surface of the semiconductor substrate is removed in a later step except for a portion formed in the trench 8.

Next, as illustrated in FIG. 17B, polysilicon doped with n-type or p-type impurity by chemical vapor deposition (CVD) or the like is deposited on the oxide film 9 in the trench 8 to form the gate trench electrode 11a, the dummy trench electrode 12a, and the diode trench electrode 21a.

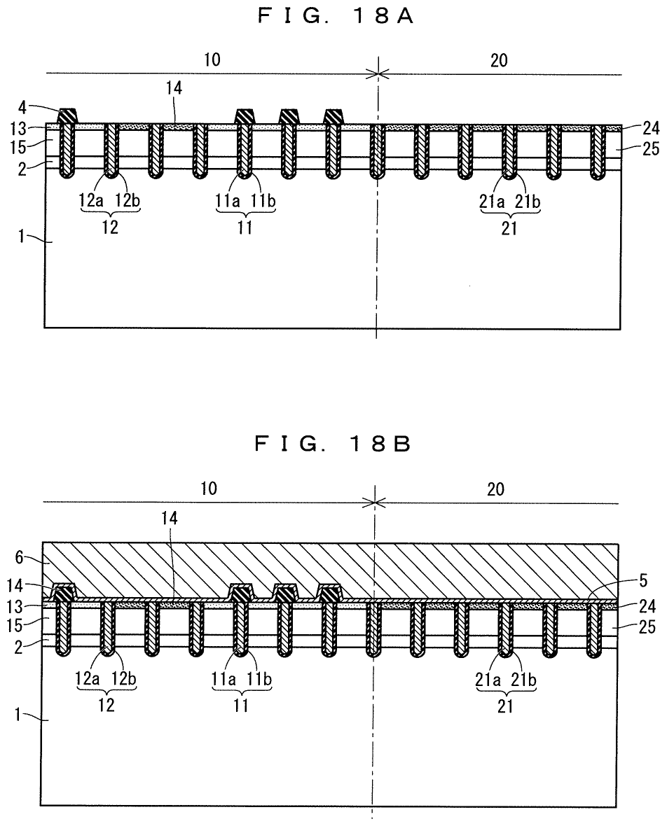

Next, as illustrated in FIG. 18A, the interlayer insulating film 4 is formed on the gate trench electrode 11a of the active trench gate 11 of the IGBT region 10. The interlayer insulating film 4 may be, for example, SiO₂. The formation of the contact hole in the deposited insulating film to be the interlayer insulating film 4 and the removal of the oxide film 9 formed on the front surface of the semiconductor substrate are performed by mask processing to form the interlayer insulating film 4 and the like in FIG. 18A. The contact hole in the interlayer insulating film 4 is formed on the n⁺-type source layer 13, the p⁺-type contact layer 14, the p⁺-type contact layer 24, the dummy trench electrode 12a, and the diode trench electrode 21a.

Next, as illustrated in FIG. 18B, the barrier metal 5 is formed on the front surface of the semiconductor substrate and the interlayer insulating film 4, and the emitter electrode 6 is further formed on the barrier metal 5. The barrier metal 5 is formed by depositing titanium nitride by physical vapor deposition (PDV) or CVD.

The emitter electrode 6 may be formed by, for example, depositing an aluminum silicon alloy (Al—Si-based alloy) on the barrier metal 5 by PVD such as sputtering or vapor deposition. A nickel alloy (Ni alloy) may be further formed on the formed aluminum silicon alloy by electroless plating or electrolytic plating to form the emitter electrode 6. By forming the emitter electrode 6 by plating, a thick metal film can be easily formed as the emitter electrode 6, and thus a heat capacity of the emitter electrode 6 can be increased to improve heat resistance. In a case where a nickel alloy is further formed by plating treatment after forming the emitter electrode 6 including an aluminum silicon alloy by PVD, the plating treatment for forming the nickel alloy may be performed after processing the back surface side of the semiconductor substrate.

Next, as illustrated in FIG. 19A, the back surface side of the semiconductor substrate is ground to thin the semiconductor substrate to a designed predetermined thickness. The thickness of the semiconductor substrate after grinding may be, for example, from 80 μm to 200 μm.

Next, as illustrated in FIG. 19B, an n-type impurity is implanted from the back surface side of the semiconductor substrate to form the n-type buffer layer 3. Furthermore, a p-type impurity is implanted from the back surface side of the semiconductor substrate to form the p-type collector layer 16. The n-type buffer layer 3 may be formed in the IGBT region 10, the diode region 20, the terminal region 30, and the like, or may be formed only in the IGBT region 10 or the diode region 20. The n-type buffer layer 3 may be formed by, for example, implanting phosphorus (P) ions, implanting protons (H⁺), or implanting both protons and phosphorus. Protons can be implanted from the back surface of the semiconductor substrate to a deep position with relatively low acceleration energy. In addition, by changing the acceleration energy, the depth at which protons are implanted can be relatively easily changed. Therefore, when the n-type buffer layer 3 is formed with protons, if implantation is performed a plurality of times while changing the acceleration energy, the n-type buffer layer 3 thicker in the thickness direction of the semiconductor substrate than that formed with phosphorus can be formed.

In addition, since phosphorus can increase an activation rate as an n-type impurity as compared with protons, by forming the n-type buffer layer 3 with phosphorus, punch-through of a depletion layer can be suppressed even in a thinned semiconductor substrate. In order to further thin the semiconductor substrate, it is preferable to form the n-type buffer layer 3 by implanting both protons and phosphorus, and in this case, protons are implanted at a position deeper than phosphorus from the back surface.

After ion implantation of the n-type impurity from the back surface side of the semiconductor substrate, the back surface is irradiated with a laser to perform laser annealing. As a result, the implanted n-type impurity is activated to form the n-type buffer layer 3.

Since protons are activated at a relatively low annealing temperature such as 350° C. to 500° C., it is necessary to pay attention so that the entire semiconductor substrate does not become a temperature higher than 350° C. to 500° C. except for in a step of activating protons after implanting protons. Laser annealing can be used to activate the n-type impurity and p-type impurity even after implantation of protons because only the vicinity of the back surface of the semiconductor substrate can be heated to a high temperature.

The p-type collector layer 16 may be formed by implanting boron (B), for example. The p-type collector layer 16 is also formed in the terminal region 30, and the p-type collector layer 16 in the terminal region 30 becomes the p-type terminal collector layer 16a. A p-type impurity is implanted in a region where the p-type collector layer 16 is formed, and an amorphous layer and a crystal defect layer are formed by implantation damage by increasing implantation energy and implantation amount. By irradiating the amorphous layer and the crystal defect layer with a laser and performing laser annealing, the amorphous layer is recrystallized, and the p-type collector layer 16 having a stepwise profile is formed. The first defect 50 is formed and controlled in the p-type collector layer 16 by adjusting the power of the laser annealing at this time and the time for laser irradiation.

Next, as illustrated in FIG. 20A, the n⁺-type cathode layer 26 is formed on the back surface side of the diode region 20. The n⁺-type cathode layer 26 may be formed by implanting, for example, arsenic (As), phosphorus (P), or the like. As illustrated in FIG. 20A, an n-type impurity is selectively implanted from the back surface side by mask processing such that a boundary between the p-type collector layer 16 and the n⁺-type cathode layer 26 is located at a position at a distance U1 from the boundary between the IGBT region 10 and the diode region 20 toward the diode region 20. An implantation amount of the n-type impurity for forming the n⁺-type cathode layer 26 is larger than an implantation amount of the p-type impurity for forming the p-type collector layer 16. In FIG. 20A, a depth of the n⁺-type cathode layer 26 is equal to or greater than a depth of the p-type collector layer 16. In the region where the n⁺-type cathode layer 26 is formed, since it is necessary to form an n-type semiconductor by implanting an n-type impurity into the region into which the p-type impurity has been implanted, the concentration of the n-type impurity is higher than the concentration of the p-type impurity implanted in the entire region where the n⁺-type cathode layer 26 is formed.

A p-type impurity and a high-concentration n-type impurity are implanted in the region where the n⁺-type cathode layer 26 is formed, and an amorphous layer is formed by implantation damage by increasing the implantation energy and the implantation amount. By irradiating the amorphous layer with a laser and performing laser annealing, the amorphous layer is recrystallized, and the n⁺-type cathode layer 26 having a stepwise profile is formed. The first defect 50 is formed and controlled in the n⁺-type cathode layer 26 by adjusting the power of the laser annealing at this time and the time for laser irradiation. The laser annealing to the region where the p-type collector layer 16 is formed and the laser annealing to the region where the n⁺-type cathode layer 26 is formed may or need not be performed simultaneously. The p-type impurity in the n⁺-type cathode layer 26 also has a stepwise profile, but functions as an n⁺-type layer because the concentration of the implanted n-type impurity is higher than the p-type impurity concentration.

Next, as illustrated in FIG. 20B, the collector electrode 7 is formed on the back surface of the semiconductor substrate. The collector electrode 7 is formed over the entire surface of the IGBT region 10, the diode region 20, the terminal region 30, and the like on the back surface. The collector electrode 7 may be formed over the entire back surface of the n-type wafer which is the semiconductor substrate. The collector electrode 7 may be formed by depositing an aluminum silicon alloy (Ai—Si-based alloy), titanium (Ti), or the like by PVD such as sputtering or vapor deposition, or may be formed by laminating a plurality of metals such as an aluminum silicon alloy, titanium, nickel, or gold. In addition, the collector electrode 7 may be formed by further forming a metal film on the metal film formed by PVD, by electroless plating or electrolytic plating.

The semiconductor device 100 is manufactured by the above steps. A plurality of semiconductor devices 100 is manufactured in a state of being integrated in a matrix on a semiconductor substrate such as one n-type wafer. Therefore, the semiconductor device 100 is individually cut by laser dicing or blade dicing.

### Summary of First Preferred Embodiment

In the semiconductor device 100 according to the first preferred embodiment as described above, the first defect 50 extending from the back surface side in the direction including the component in the thickness direction is provided in the n⁺-type cathode layer 26 of the diode region 20. In such a configuration, by controlling the first defect 50, the forward characteristic and a recovery loss (Erec) as the switching loss can be adjusted in a range in which an on-voltage (VF) of the diode achieved in the diode region 20 is low.

In the first preferred embodiment, the first defect 50 extending from the back surface side in the direction including the component in the thickness direction is provided in the p-type collector layer 16 of the IGBT region 10. In such a configuration, by controlling the first defect 50, the forward characteristic and a turn-off loss (Eoff) as the switching loss can be adjusted in a range in which an on-voltage (Vsat) of the IGBT achieved in the IGBT region 10 is low.

<Modifications>

In the first preferred embodiment, the first defect 50 is provided in both the p-type collector layer 16 of the IGBT region 10 and the n⁺-type cathode layer 26 of the diode region 20. However, the first defect 50 may be provided in any one of the p-type collector layer 16 of the IGBT region 10 or the n⁺-type cathode layer 26 of the diode region 20. In the first preferred embodiment, the first defect 50 is provided in the boundary region (see FIG. 9) between the IGBT region 10 and the diode region 20, but the first defect 50 may be provided in the IGBT region 10 (see FIGS. 3 to 5) and the diode region 20 (see FIGS. 6 to 8) other than the boundary region. The same applies to second and subsequent preferred embodiments.

### Second Preferred Embodiment

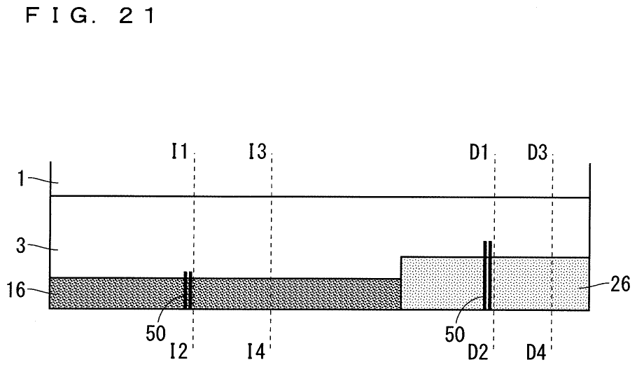

FIG. 21 is an enlarged sectional view of a part of the boundary region in the semiconductor device 100 according to the second preferred embodiment, and corresponds to FIG. 10. In the second preferred embodiment, in the diode region 20, the n-type buffer layer 3 is provided on the opposite side of the back surface with respect to the n⁺-type cathode layer 26, and the first defect 50 in the n⁺-type cathode layer 26 penetrates the n⁺-type cathode layer 26 and reaches the n-type buffer layer 3 in the diode region 20. In the IGBT region 10, the n-type buffer layer 3 is provided on the opposite side of the back surface with respect to the p-type collector layer 16, and the first defect in the p-type collector layer 16 penetrates the p-type collector layer 16 and reaches the n-type buffer layer 3 in the IGBT region 10. Neither the first defect 50 in the n⁺-type cathode layer 26 nor the first defect 50 in the p-type collector layer 16 penetrates the n-type buffer layer 3.

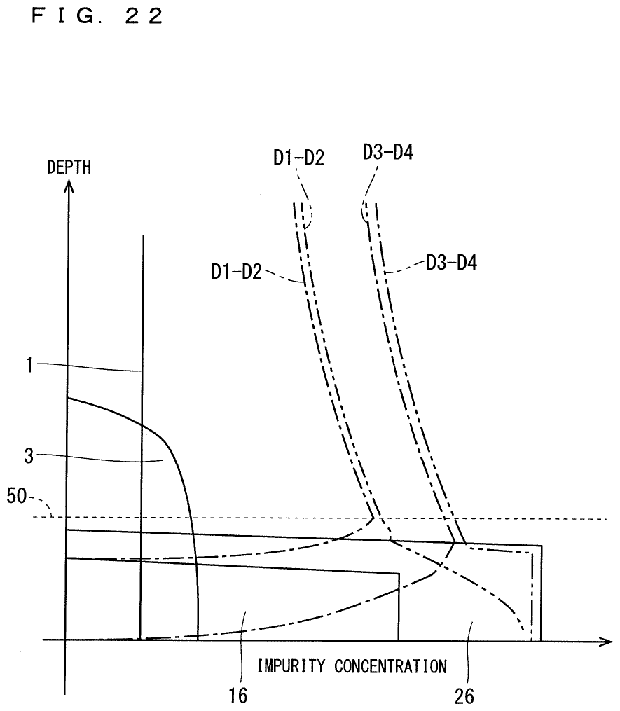

FIG. 22 is a diagram illustrating a relationship between the depth from the back surface, the impurity concentration, and the carrier density in the on state in the diode region 20 according to the second preferred embodiment, and corresponds to FIG. 11. In FIG. 22, as in FIG. 11, the carrier density of the portion along the line D1-D2 where the first defect 50 is provided is lower than the carrier density of the portion along the line D3-D4 where the first defect 50 is not provided. In the second preferred embodiment, since the first defect 50 reaches the n-type buffer layer 3, an extent to which the carrier density decreases in the portion where the first defect 50 is provided is larger than that in the first preferred embodiment, and the on-voltage (VF) increases. Therefore, in the second preferred embodiment, the forward characteristic is further deteriorated, but the switching loss is further improved. As a result, in the second preferred embodiment, the range in which the forward characteristic and the switching loss can be adjusted can be expanded as compared with the first preferred embodiment.

Note that when the depletion layer reaches the first defect 50 at during reverse bias, a leakage current increases. Therefore, depending on the depth of the first defect 50, the impurity concentration and the depth of the n-type buffer layer 3 may be adjusted.

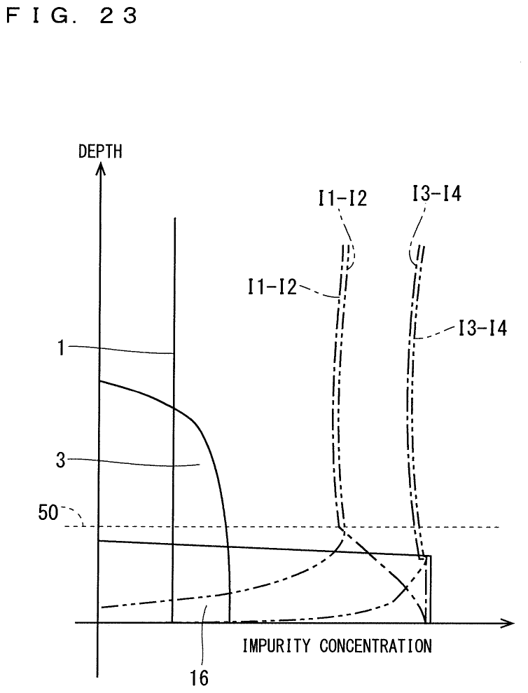

FIG. 23 is a diagram illustrating a relationship between the depth from the back surface, the impurity concentration, and the carrier density in the on state in the IGBT region 10 according to the second preferred embodiment, and corresponds to FIG. 12. In FIG. 23, as in FIG. 12, the carrier density of the portion along the line 11-12 where the first defect 50 is provided is lower than the carrier density of the portion along the line 13-14 where the first defect 50 is not provided. In the second preferred embodiment, since the first defect 50 reaches the n-type buffer layer 3, the extent to which the carrier density decreases in the portion where the first defect 50 is provided is larger than that in the first preferred embodiment, and the on-voltage (Vsat) increases. Therefore, in the second preferred embodiment, the forward characteristic is further deteriorated, but the switching loss is further improved. As a result, in the second preferred embodiment, the range in which the forward characteristic and the switching loss can be adjusted can be expanded as compared with the first preferred embodiment.

Note that when the depletion layer reaches the first defect 50 at during reverse bias, a leakage current increases. Therefore, depending on the depth of the first defect 50, the impurity concentration and the depth of the n-type buffer layer 3 may be adjusted.

### Summary of Second Preferred Embodiment

In the semiconductor device 100 according to the second preferred embodiment as described above, the first defect 50 in the n⁺-type cathode layer 26 penetrates the n⁺-type cathode layer 26 and reaches the n-type buffer layer 3 in the diode region 20. Such a configuration can expand the range in which the forward characteristic and the recovery loss (Erec) as switching loss can be adjusted.

In the second preferred embodiment, the first defect 50 in the p-type collector layer 16 penetrates the p-type collector layer 16 and reaches the n-type buffer layer 3 in the IGBT region 10. Such a configuration can expand the range in which the forward characteristic and the recovery loss (Eoff) as the switching loss can be adjusted.

<Modifications>

In the second preferred embodiment, both the first defect 50 in the p-type collector layer 16 and the first defect 50 in the n⁺-type cathode layer 26 reach the n-type buffer layer 3. However, any one of the first defect 50 in the p-type collector layer 16 or the first defect 50 in the n⁺-type cathode layer 26 may reach the n-type buffer layer 3 while the other does not reach the n-type buffer layer 3. The first defect 50 reaching the n-type buffer layer 3 may be provided in any one of the p-type collector layer 16 or the n⁺-type cathode layer 26 while the first defect 50 is not provided in the other. Such a configuration can finely adjust the forward characteristic and the switching loss.

### Third Preferred Embodiment

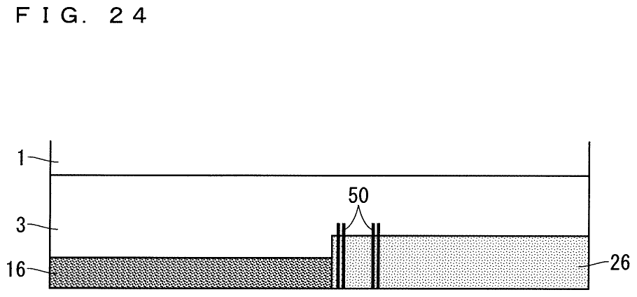

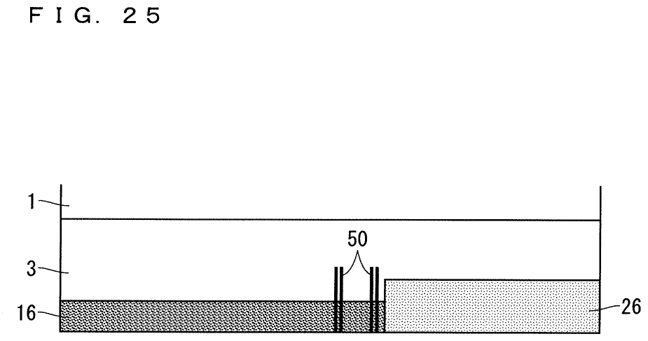

FIGS. 24 and 25 are enlarged sectional views of a part of the boundary region in the semiconductor device 100 according to a third preferred embodiment, and correspond to FIG. 10.

In a case where the first defect 50 is provided in the n⁺-type cathode layer 26 as illustrated in FIG. 24, the first defect 50 may be provided close to the p-type collector layer 16, that is, provided on the boundary side between the IGBT region 10 and the diode region 20. In a case where the first defect 50 is provided in the p-type collector layer 16 as illustrated in FIG. 25, the first defect 50 may be provided close to the n⁺-type cathode layer 26, that is, provided on the boundary side between the IGBT region 10 and the diode region 20.

### Summary of Third Preferred Embodiment

In the semiconductor device 100 according to the third preferred embodiment as described above, the first defect 50 is provided on the boundary side between the IGBT region 10 and the diode region 20. Such a configuration can suppress interference between the diode achieved by the diode region 20 and the IGBT achieved by the IGBT region 10.

<Modifications>

In the third preferred embodiment, the first defect 50 is provided in any one of the p-type collector layer 16 or the n⁺-type cathode layer 26, but may be provided in both the p-type collector layer 16 and the n⁺-type cathode layer 26. In addition, the p-type collector layer 16 in which the first defect 50 is provided and the n⁺-type cathode layer 26 in which the first defect 50 is provided may be alternately provided along the boundary between the p-type collector layer 16 and the n⁺-type cathode layer 26. In the third preferred embodiment, the first defect 50 reaches the n-type buffer layer 3, but is not required to reach the n-type buffer layer 3.

### Fourth Preferred Embodiment

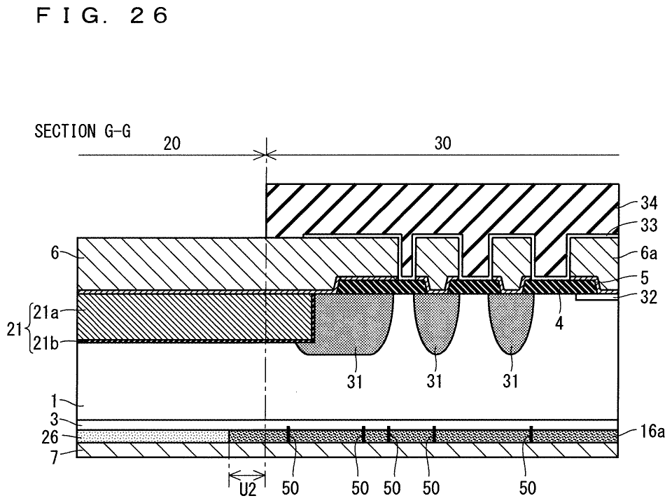

FIG. 26 is a sectional view illustrating a configuration of the terminal region 30 of the semiconductor device 100 according to a fourth preferred embodiment, and corresponds to FIG. 14. In the fourth preferred embodiment, the p-type terminal collector layer 16a is provided as the semiconductor layer on the back surface side of the terminal region 30 included in a semiconductor region, and a first defect 50 extending from the back surface side in the direction including a component in the thickness direction is provided in the p-type terminal collector layer 16a. Then, in the terminal region 30, the n-type buffer layer 3 is provided on the opposite side of the back surface with respect to the p-type terminal collector layer 16a, and the first defect 50 in the p-type terminal collector layer 16a penetrates the p-type terminal collector layer 16a and reaches the n-type buffer layer 3 in the terminal region 30.

### Summary of Fourth Preferred Embodiment

In the semiconductor device 100 according to the fourth preferred embodiment as described above, since the implantation of carriers from the back surface of the terminal region 30 can be reduced, an avalanche resistance characteristic can be improved.

<Modifications>

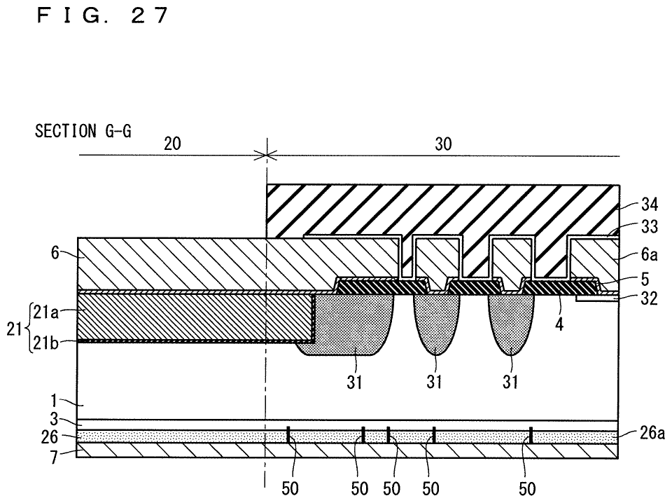

FIG. 27 is a sectional view illustrating a configuration of the terminal region 30 of the semiconductor device 100 according to the present modification. In the fourth preferred embodiment, the p-type terminal collector layer 30 is provided in the terminal region 16a, but as illustrated in FIG. 27, an n⁺-type terminal cathode layer 26a continuous from the n⁺-type cathode layer 26 provided in the diode region 20 of the cell region may be provided. Then, the first defect 50 extending from the back surface side in the direction including the component in the thickness direction may penetrate the n⁺-type termination cathode layer 26a and reach the n-type buffer layer 3 in the terminal region 30. In the terminal region 30, the p-type terminal collector layer 16a provided with the first defect 50 and the n⁺-type terminal cathode layer 26a provided with the first defect 50 may be alternately provided.

### Fifth Preferred Embodiment

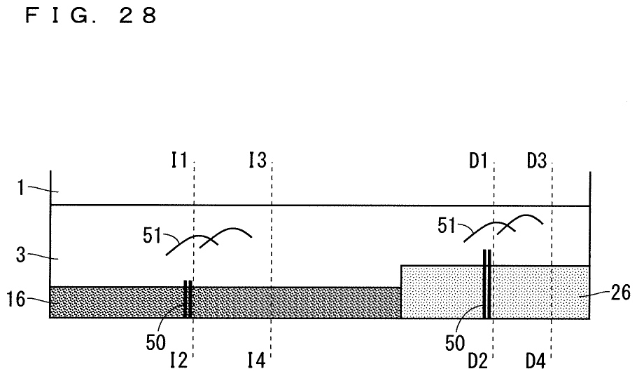

FIG. 28 is an enlarged sectional view of a part of the boundary region in the semiconductor device 100 according to a fifth preferred embodiment, and corresponds to FIG. 21. The fifth preferred embodiment includes a second defect 51 extending in a direction including a component in the thickness direction and a component in the in-plane direction, in addition to the configuration of the second preferred embodiment.

The second defect 51 is provided in the n-type buffer layer 3 in each of the IGBT region 10 and the diode region 20. As for the direction in which the second defect 51 extends, the component in the thickness direction (the component in the up-down direction in FIG. 28) and the component in the in-plane direction (the component in the left-right direction in FIG. 28) may be the same. That is, the second defect 51 may extend in an oblique direction in FIG. 28.

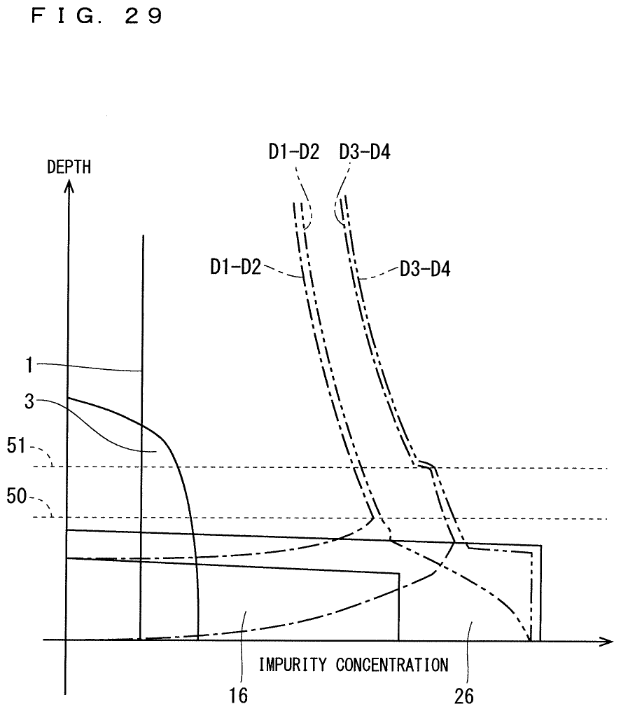

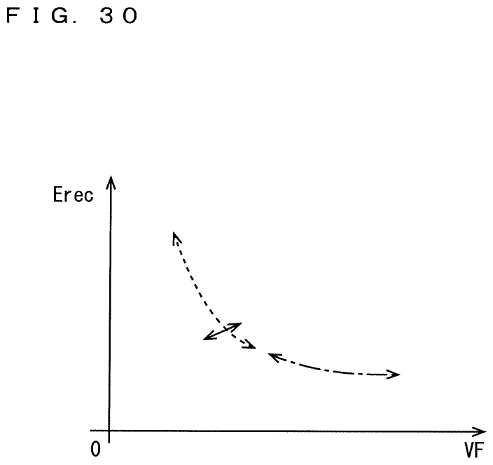

FIG. 29 is a diagram illustrating a relationship between the depth from the back surface, the impurity concentration, and the carrier density in the on state in the diode region 20 according to the fifth preferred embodiment, and corresponds to FIG. 22. Similarly to the first defect 50, the position of the portion farthest from the back surface of the second defect 51 is indicated by a dotted line. The same applies to FIG. 30 and the like which are similar to FIG. 29. As illustrated in FIG. 29, the carrier density of the portion along the line D1-D2 is further reduced by the second defect 51. By adjusting a depth of the second defect 51 so as to match the region where the depletion layer extends during a recovery operation, a tail current of the recovery operation is suppressed, and thus the trade-off relationship between the forward characteristic and the switching loss can be improved.

FIG. 30 is a diagram illustrating a relationship of the semiconductor device 100 according to the first, second, and fifth preferred embodiments. As illustrated in FIG. 30, in the configuration of the first preferred embodiment (that is, a configuration in which the first defect 50 that does not reach the n-type buffer layer 3 is provided in the n⁺-type cathode layer 26), the forward characteristic and the recovery loss (Erec) can be adjusted within the range of the arrow of a dotted line. In the configuration of the second preferred embodiment (that is, a configuration in which the first defect 50 that reaches the n-type buffer layer 3 is provided in the n⁺-type cathode layer 26), the forward characteristic and the recovery loss (Erec) can be adjusted within the range of the arrow of an alternate long and short dash line. In the configuration of the fifth preferred embodiment (that is, the configuration in which the second defect 51 is provided in the n-type buffer layer 3 of the diode region 20), the forward characteristic and the recovery loss (Erec) can be adjusted in the range of the solid arrow.

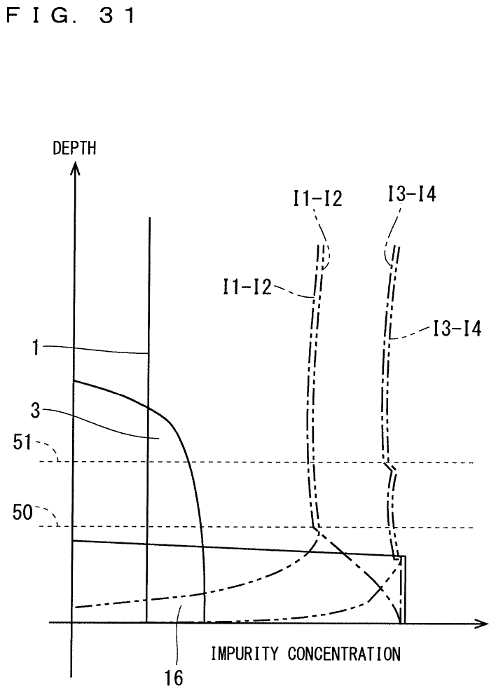

FIG. 31 is a diagram illustrating a relationship between the depth from the back surface, the impurity concentration, and the carrier density in the on state in the IGBT region 10 according to the fifth preferred embodiment, and corresponds to FIG. 23. As illustrated in FIG. 31, the carrier density of the portion along the line 11-12 is further reduced by the second defect 51. By adjusting a depth of the second defect 51 so as to match the region where the depletion layer extends during a recovery operation, a tail current of the recovery operation is suppressed, and thus the trade-off relationship between the forward characteristic and the switching loss can be improved.

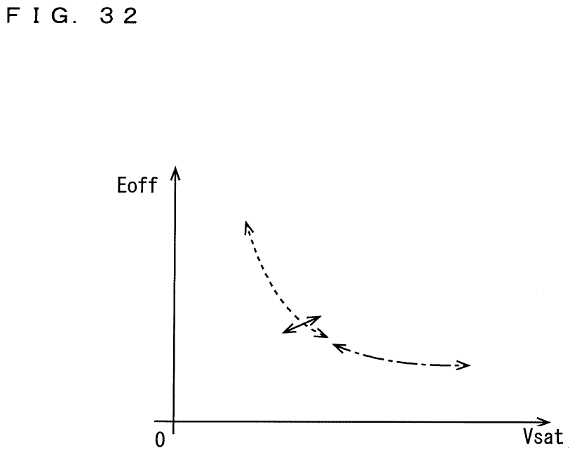

FIG. 32 is a diagram illustrating a relationship of the semiconductor device 100 according to the first, second, and fifth preferred embodiments. As illustrated in FIG. 32, in the configuration of the first preferred embodiment (that is, a configuration in which the first defect 50 that does not reach the n-type buffer layer 3 is provided in the p-type collector layer 16), the forward characteristic and the turn-off loss (Eoff) can be adjusted within the range of the arrow of a dotted line. In the configuration of the second preferred embodiment (that is, a configuration in which the first defect 50 that reaches the n-type buffer layer 3 is provided in the p-type collector layer 16), the forward characteristic and the turn-off loss (Eoff) can be adjusted within the range of the arrow of the alternate long and short dash line. In the configuration of the fifth preferred embodiment (that is, the configuration in which the second defect 51 is provided in the n-type buffer layer 3 in the IGBT region 10), the forward characteristic and the turn-off loss (Eoff) can be adjusted in the range of the solid arrow.

<Manufacturing Method>

Hereinafter, in the method for manufacturing the semiconductor device according to the fifth preferred embodiment, steps of forming the first defect 50 and the second defect 51 will be described.

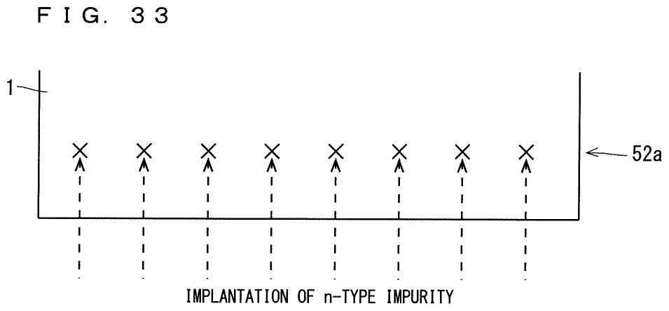

After the back surface side of the semiconductor substrate is ground, as illustrated in FIG. 33, an n-type impurity is implanted into the IGBT region 10 and the diode region 20 of the semiconductor substrate from the back surface side. The n-type impurity includes at least one of a phosphorus ion or protons. By implantation of the n-type impurity, a second implantation layer 52a as a crystal defect layer is formed in the IGBT region 10 and the diode region 20 on the back surface side.

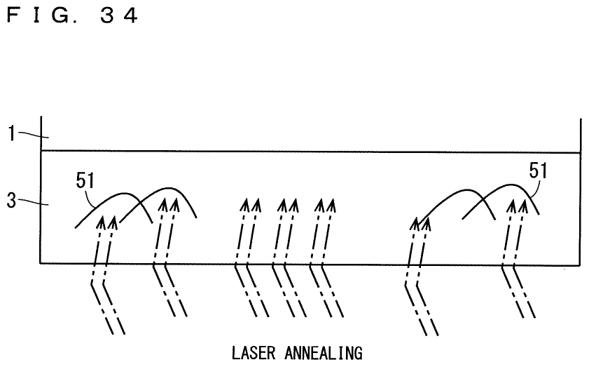

Next, as illustrated in FIG. 34, laser annealing is performed by irradiating the second implantation layer 52a with a laser. As a result, the implanted n-type impurity is activated to form the n-type buffer layer 3. In addition, the second defect 51 is formed by partially maintaining the defect by adjusting the power of laser annealing or the time for laser irradiation.

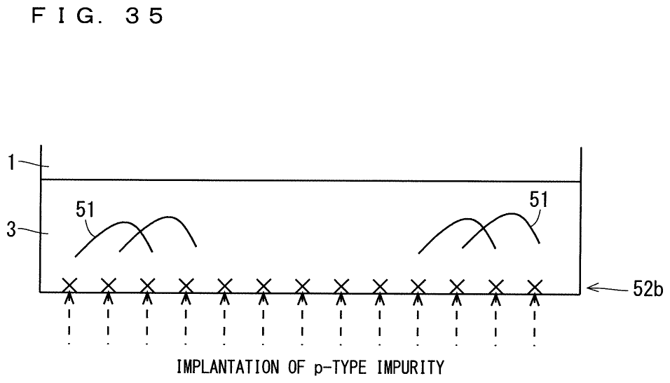

Then, as illustrated in FIG. 35, a p-type impurity is implanted into the IGBT region 10 and the diode region 20 of the semiconductor substrate from the back surface side. The p-type impurity includes at least one of a boron ion or a BF₂ ion. By implantation of the p-type impurity, a first implantation layer 52b including a crystal defect layer and an amorphous layer is formed in the IGBT region 10 and the diode region 20 on the back surface side.

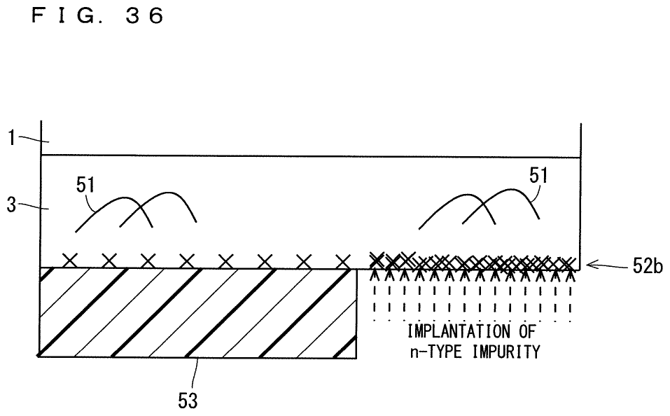

Next, as illustrated in FIG. 36, a resist 53 is formed in a part of the IGBT region and the diode region 20 of the semiconductor substrate. Then, an n-type impurity is implanted into the remaining part of the diode region 20 of the semiconductor substrate from the back surface side. The n-type impurity includes at least one of a phosphorus ion or an arsenic ion. By implantation of the n-type impurity, the first implantation layer 52b which is an amorphous layer is formed in the remaining part of the diode region 20 on the back surface side.

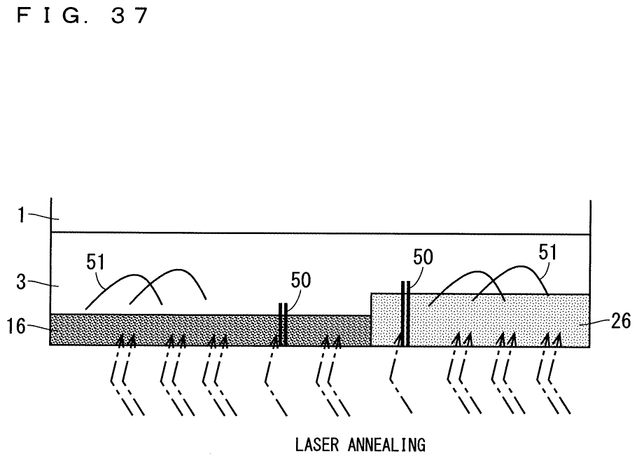

Then, as illustrated in FIG. 37, the resist 53 is removed, and the first implantation layer 52b is irradiated with a laser to perform laser annealing. As a result, the implanted p-type impurity and n-type impurity are activated to form the p-type collector layer 16 and the n⁺-type cathode layer 26. In addition, the first defect 50 is formed by recrystallizing the first implantation layer 52b or partially maintaining the defect by adjusting the power of laser annealing or the time for laser irradiation. In the remaining part of the diode region 20, since the concentration of the implanted n-type impurity is higher than the p-type impurity concentration, the n⁺-type cathode layer 26 is formed.

### Summary of Fifth Preferred Embodiment

In the semiconductor device 100 according to the fifth preferred embodiment as described above, the second defect 51 extending in the direction including the component in the thickness direction and the component in the in-plane direction is provided in the n-type buffer layer 3 in each of the IGBT region 10 and the diode region 20. Such a configuration can improve the trade-off relationship between the forward characteristic and the switching loss.

<Modifications>

In the fifth preferred embodiment, the second defect 51 is provided in the n-type buffer layer 3 in each of the IGBT region 10 and the diode region 20. However, the second defect 51 may be provided in the n-type buffer layer 3 in any one of the IGBT region 10 or the diode region 20. In a case where the second defect 51 is provided in the n-type buffer layer 3 in the diode region 20, the first defect 50 is not required to be provided in the p-type collector layer 16, or the first defect 50 that reaches or does not reach the n-type buffer layer 3 may be provided in the p-type collector layer 16. Similarly, in a case where the second defect 51 is provided in the n-type buffer layer 3 in the IGBT region 10, the first defect 50 is not required to be provided in the n⁺-type cathode layer 26, or the first defect 50 that reaches or does not reach the n-type buffer layer 3 may be provided in the n⁺-type cathode layer 26.

### Sixth Preferred Embodiment

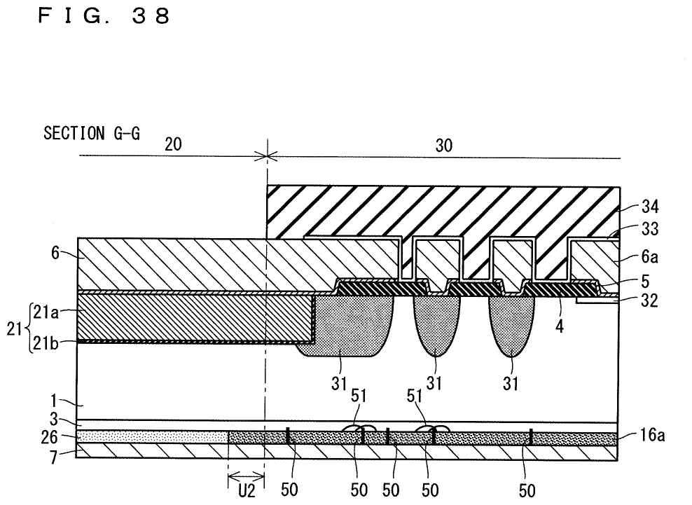

FIG. 38 is a sectional view illustrating a configuration of the terminal region 30 of the semiconductor device 100 according to a sixth preferred embodiment, and corresponds to FIG. 26. In the sixth preferred embodiment, as in the fourth preferred embodiment, the first defect 50 penetrates the p-type terminal collector layer 16a and reaches the n-type buffer layer 3 in the terminal region 30.

In the sixth preferred embodiment, the second defect 51 extending in the direction including the component in the thickness direction and the component in the in-plane direction is provided in the n-type buffer layer 3 in the terminal region 30. That is, the second defect 51 similar to the second defect 51 according to the fifth preferred embodiment is provided in the n-type buffer layer 3 in the terminal region 30.

### Summary of Sixth Preferred Embodiment

In the semiconductor device 100 according to the sixth preferred embodiment as described above, the second defect 51 extending in the direction including the component in the thickness direction and the component in the in-plane direction is provided in the n-type buffer layer 3 in the terminal region 30. As a result, since the number of carriers in the terminal region 30 is reduced, a safe operation region (SOA) can be improved.

<Modifications>

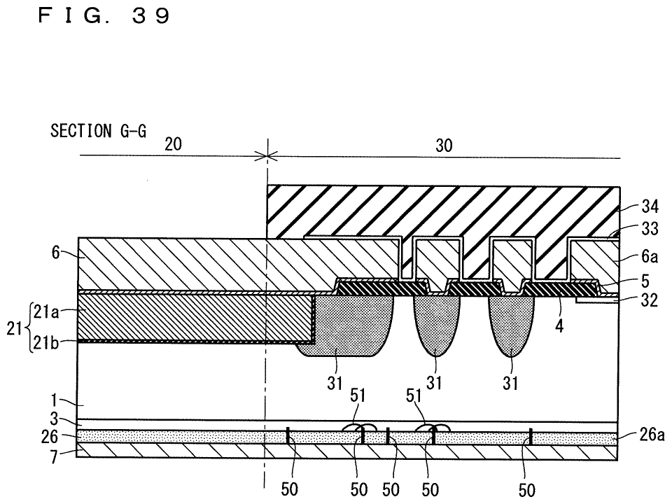

FIG. 39 is a sectional view illustrating a configuration of the terminal region 30 of the semiconductor device 100 according to the present modification, and corresponds to FIG. 27. As illustrated in FIG. 39, in the configuration in which the first defect 50 penetrates the n⁺-type terminal cathode layer 26a and reaches the n-type buffer layer 3 in the terminal region 30, the second defect 51 may be also provided in the n-type buffer layer 3 in the terminal region 30. In the terminal region 30, the p-type terminal collector layer 16a provided with the first defect 50 and the second defect 51 and the n⁺-type terminal cathode layer 26a provided with the first defect 50 and the second defect 51 may be alternately provided.

Note that the preferred embodiments and the modifications can be freely combined, and the preferred embodiments and the modifications can be appropriately modified or omitted.

Hereinafter, various aspects of the present disclosure will be collectively described as supplementary notes.

(Supplementary Note 1)

A semiconductor device including:
a semiconductor region in which a semiconductor layer is provided on a main surface side of the semiconductor region; and
a first defect provided in the semiconductor layer and extending from the main surface side in a direction including a component in a thickness direction,
in which the semiconductor region includes at least one of a diode region in which a cathode layer is provided as the semiconductor layer or an IGBT region in which a collector layer is provided as the semiconductor layer.

(Supplementary Note 2)

The semiconductor device according to Supplementary Note 1, in which
the semiconductor region includes the diode region,
a buffer layer is provided on an opposite side of the main surface with respect to the cathode layer in the diode region, and
the first defect in the cathode layer penetrates the cathode layer and reaches the buffer layer in the diode region.

(Supplementary Note 3)

The semiconductor device according to Supplementary Note 1, in which
the semiconductor region includes the IGBT region,
a buffer layer is provided on an opposite side of the main surface with respect to the collector layer in the IGBT region, and
the first defect in the collector layer penetrates the collector layer and reaches the buffer layer in the IGBT region.

(Supplementary Note 4)

The semiconductor device according to Supplementary Note 1, in which
the semiconductor region includes the diode region and the IGBT region,
a buffer layer is provided on an opposite side of the main surface with respect to the cathode layer and the collector layer in the diode region and the IGBT region,
the first defect in the cathode layer penetrates the cathode layer and reaches the buffer layer in the diode region, and
the first defect in the collector layer penetrates the collector layer and reaches the buffer layer in the IGBT region.

(Supplementary Note 5)

The semiconductor device according to any one of Supplementary notes 1 to 4, in which the first defect is provided on a boundary side between the IGBT region and the diode region.

(Supplementary Note 6)

The semiconductor device according to any one of Supplementary notes 1 to 5, in which
the semiconductor region further includes a terminal region in which at least one layer of a terminal cathode layer or a terminal collector layer is provided as the semiconductor layer,
a buffer layer is provided on an opposite side of the main surface with respect to the at least one layer in the terminal region, and
the first defect in the terminal region penetrates the at least one layer and reaches the buffer layer in the terminal region.

(Supplementary Note 7)

The semiconductor device according to Supplementary Note 2, further including a second defect provided in the buffer layer in the diode region and extending in a direction including the component in the thickness direction and a component in an in-plane direction.

(Supplementary Note 8)

The semiconductor device according to Supplementary Note 3, further including a second defect provided in the buffer layer in the IGBT region and extending in a direction including the component in the thickness direction and a component in an in-plane direction.

(Supplementary Note 9)

The semiconductor device according to Supplementary Note 4, further including a second defect provided in the buffer layer in each of the diode region and the IGBT region and extending in a direction including the component in the thickness direction and a component in an in-plane direction.

(Supplementary Note 10)

The semiconductor device according to Supplementary Note 6, further including a second defect provided in the buffer layer in the terminal region and extending in a direction including the component in the thickness direction and a component in an in-plane direction.

(Supplementary Note 11)

The semiconductor device according to any one of Supplementary notes 1 to 10, in which the semiconductor device is an RC-IGBT including one semiconductor substrate provided with the diode region and the IGBT region.

(Supplementary Note 12)

A method for manufacturing a semiconductor device, the method including:
forming a first implantation layer on a main surface side of a semiconductor region; and
by subjecting a portion to be the semiconductor layer in the first implantation layer to heat treatment, forming the semiconductor layer and forming, in the semiconductor layer, a first defect extending from the main surface side in a direction including a component in a thickness direction,
in which the semiconductor region includes at least one of a diode region in which a cathode layer is provided as the semiconductor layer or an IGBT region in which a collector layer is provided as the semiconductor layer.

(Supplementary Note 13)

The method for manufacturing a semiconductor device according to Supplementary Note 12, further including:
forming a second implantation layer on the main surface side of the semiconductor region; and
by subjecting a portion of the second implantation layer to be a buffer layer to heat treatment, forming the buffer layer and forming, in the buffer layer, a second defect extending in a direction including the component in the thickness direction and a component in an in-plane direction.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor region in which a semiconductor layer is provided on a main surface side of the semiconductor region; and
a first defect provided in the semiconductor layer and extending from the main surface side in a direction including a component in a thickness direction,
wherein the semiconductor region includes at least one of a diode region in which a cathode layer is provided as the semiconductor layer or an IGBT region in which a collector layer is provided as the semiconductor layer.

2. The semiconductor device according to claim 1, wherein
the semiconductor region includes the diode region,
a buffer layer is provided on an opposite side of the main surface with respect to the cathode layer in the diode region, and
the first defect in the cathode layer penetrates the cathode layer and reaches the buffer layer in the diode region.

3. The semiconductor device according to claim 1, wherein
the semiconductor region includes the IGBT region,
a buffer layer is provided on an opposite side of the main surface with respect to the collector layer in the IGBT region, and
the first defect in the collector layer penetrates the collector layer and reaches the buffer layer in the IGBT region.

4. The semiconductor device according to claim 1, wherein
the semiconductor region includes the diode region and the IGBT region,
a buffer layer is provided on an opposite side of the main surface with respect to the cathode layer and the collector layer in the diode region and the IGBT region,
the first defect in the cathode layer penetrates the cathode layer and reaches the buffer layer in the diode region, and
the first defect in the collector layer penetrates the collector layer and reaches the buffer layer in the IGBT region.

5. The semiconductor device according to claim 1, wherein the first defect is provided on a boundary side between the IGBT region and the diode region.

6. The semiconductor device according to claim 1, wherein
the semiconductor region further includes a terminal region in which at least one layer of a terminal cathode layer or a terminal collector layer is provided as the semiconductor layer,
a buffer layer is provided on an opposite side of the main surface with respect to the at least one layer in the terminal region, and
the first defect in the terminal region penetrates the at least one layer and reaches the buffer layer in the terminal region.

7. The semiconductor device according to claim 2, further comprising a second defect provided in the buffer layer in the diode region and extending in a direction including the component in the thickness direction and a component in an in-plane direction.

8. The semiconductor device according to claim 3, further comprising a second defect provided in the buffer layer in the IGBT region and extending in a direction including the component in the thickness direction and a component in an in-plane direction.

9. The semiconductor device according to claim 4, further comprising a second defect provided in the buffer layer in each of the diode region and the IGBT region and extending in a direction including the component in the thickness direction and a component in an in-plane direction.

10. The semiconductor device according to claim 6, further comprising a second defect provided in the buffer layer in the terminal region and extending in a direction including the component in the thickness direction and a component in an in-plane direction.

11. The semiconductor device according to claim 1, wherein the semiconductor device is an RC-IGBT including one semiconductor substrate provided with the diode region and the IGBT region.

12. A method for manufacturing a semiconductor device, the method comprising:
forming a first implantation layer on a main surface side of a semiconductor region; and
by subjecting a portion to be the semiconductor layer in the first implantation layer to heat treatment, forming the semiconductor layer and forming, in the semiconductor layer, a first defect extending from the main surface side in a direction including a component in a thickness direction,
wherein the semiconductor region includes at least one of a diode region in which a cathode layer is provided as the semiconductor layer or an IGBT region in which a collector layer is provided as the semiconductor layer.

13. The method for manufacturing a semiconductor device according to claim 12, further comprising:
forming a second implantation layer on the main surface side of the semiconductor region; and
by subjecting a portion of the second implantation layer to be a buffer layer to heat treatment, forming the buffer layer and forming, in the buffer layer, a second defect extending in a direction including the component in the thickness direction and a component in an in-plane direction.
